(19) United States
(12) Patent Application Publication
(10) Pub. No.: US 2023/0063147 A1
(43) Pub. Date: Mar. 2, 2023

(54) SEMICONDUCTOR PACKAGE

(71) Applicant: Samsung Electronics Co., Ltd., Suwon-si (KR)

(72) Inventor: Hae-Jung YU, Hwaseong-si (KR)

(73) Assignee: Samsung Electronics Co., Ltd., Suwon-si (KR)

(21) Appl. No.: 17/853,237

(22) Filed: Jun. 29, 2022

(30) Foreign Application Priority Data
Aug. 31, 2021 (KR) 10-2021-0115602

(51) Int. Cl. H01L 25/18; H01L 23/31; H01L 23/00; H01L 23/498

(52) U.S. Cl. CPC H01L 25/18; H01L 23/3157; H01L 24/16; H01L 24/32; H01L 24/73; H01L 23/49816; H01L 2224/16227; H01L 2224/32225; H01L 2224/73204; H01L 2224/16145; H01L 2224/32145; H01L 24/29; H01L 2224/2919; H01L 2924/0665

(57) ABSTRACT

A semiconductor package includes a substrate and a first semiconductor chip on the substrate and having a first sidewall and a second sidewall different from the first sidewall. A second semiconductor chip is on the substrate and is laterally spaced apart from the first semiconductor chip. A molding layer is on the substrate and between the first sidewall of the first semiconductor chip and a sidewall of the second semiconductor chip. The molding layer exposes the second sidewall of the first semiconductor chip.

### CROSS-REFERENCE TO RELATED APPLICATION

This U.S. nonprovisional application claims priority under 35 U.S.C § 119 to Korean Patent Application No. 10-2021-0115602 filed on Aug. 31, 2021 in the Korean Intellectual Property Office, the disclosure of which is hereby incorporated by reference in its entirety.

### BACKGROUND

The present inventive concepts relate to a semiconductor package, and more particularly, to a semiconductor package including an interposer substrate.

A semiconductor package is provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. With the development of the electronics industry, various studies have been conducted to improve reliability and durability of semiconductor packages.

### SUMMARY

Some embodiments of the present inventive concepts provide a semiconductor package with increased reliability and a method of fabricating the same.

According to some embodiments of the present inventive concepts, a semiconductor package may comprise: a substrate; a first semiconductor chip on the substrate, the first semiconductor chip having a first sidewall and a second sidewall different from the first sidewall; a second semiconductor chip provided on the substrate and laterally spaced apart from the first semiconductor chip; and a molding layer on the substrate between the first sidewall of the first semiconductor chip and a sidewall of the second semiconductor chip. The molding layer may expose the second sidewall of the first semiconductor chip.

According to some embodiments of the present inventive concepts, a semiconductor package may comprise: a substrate that has a central region and an edge region when viewed in plan; a first semiconductor chip on the central region of the substrate, the first semiconductor chip having a first sidewall and a second sidewall that are different from each other; a plurality of bumps between the substrate and the first semiconductor chip; a second semiconductor chip provided on the central region of the substrate and laterally spaced apart from the first semiconductor chip; and a molding layer on the central region and the edge region of the substrate, the molding layer covering the first sidewall of the first semiconductor chip and a sidewall of the second semiconductor chip. When viewed in plan, the edge region of the substrate may be between the second sidewall of the first semiconductor chip and a sidewall of the substrate. A height of the molding layer on the edge region of the substrate may be less than a height of the plurality of bumps.

According to some embodiments of the present inventive concepts, a semiconductor package may comprise: a package substrate; a plurality of solder terminals on a bottom surface of the package substrate; an interposer substrate on a top surface of the package substrate; a plurality of connection solders between the package substrate and the interposer substrate; a first semiconductor chip on a top surface of the interposer substrate, the first semiconductor chip having a first sidewall and a second sidewall different from the first sidewall; a second semiconductor chip provided on the top surface of the interposer substrate and laterally spaced apart from the first semiconductor chip; a plurality of first bumps between the interposer substrate and the first semiconductor chip; a plurality of second bumps between the interposer substrate and the second semiconductor chip; an under-fill layer between the interposer substrate and the first semiconductor chip, the under-fill layer encapsulating the first bumps; and a molding layer on the interposer substrate, the molding layer covering the first sidewall of the first semiconductor chip and a sidewall of the second semiconductor chip. The interposer substrate may include a semiconductor die, a plurality of through vias, a plurality of wiring structures, and a plurality of interposer pads. The first semiconductor chip may include a first semiconductor die and a plurality of conductive pads. The second semiconductor chip may include a second semiconductor chip and a plurality of chip pads. A coefficient of thermal expansion of the molding layer may be greater than a coefficient of thermal expansion of the semiconductor die, greater than a coefficient of thermal expansion of the first semiconductor die, and greater than a coefficient of thermal expansion of the second semiconductor die. The molding layer may externally expose the second sidewall of the first semiconductor chip.

### BRIEF DESCRIPTION OF THE DRAWINGS

The drawings described herein are for illustrative purposes only of selected embodiments and not all possible implementations, and are not intended to limit the scope of the present disclosure.

FIG. 1A illustrates a plan view showing a semiconductor package according to some embodiments.

FIG. 1B illustrates a cross-sectional view taken along line I-I′ of FIG. 1A.

FIG. 1C illustrates an enlarged view showing section Z of FIG. 1B.

FIG. 1D illustrates a cross-sectional view taken along line II-II′ of FIG. 1A.

FIG. 1E illustrates a cross-sectional view taken along line of FIG. 1A.

FIG. 2A illustrates a cross-sectional view showing a molding layer according to some embodiments.

FIG. 2B illustrates a cross-sectional view showing a molding layer according to some embodiments.

FIG. 2C illustrates a cross-sectional view showing a molding layer according to some embodiments.

FIG. 2D illustrates a cross-sectional view showing a molding layer according to some embodiments.

FIG. 3A illustrates a cross-sectional view showing a semiconductor package according to some embodiments.

FIG. 3B illustrates an enlarged cross-sectional view showing section Z of FIG. 3A.

FIG. 4A illustrates a cross-sectional view showing a semiconductor package according to some embodiments.

FIG. 4B illustrates a cross-sectional view showing a semiconductor package according to some embodiments.

FIG. 5A illustrates a cross-sectional view showing a semiconductor package according to some embodiments.

FIG. 5B illustrates a cross-sectional view showing a semiconductor package according to some embodiments.

FIG. 5C illustrates a cross-sectional view showing a semiconductor package according to some embodiments.

FIG. 6A illustrates a plan view showing a semiconductor package according to some embodiments.

FIG. 6B illustrates a cross-sectional view taken along line of FIG. 6A.

FIG. 6C illustrates a plan view showing a semiconductor package according to some embodiments.

FIG. 6D illustrates a cross-sectional view taken along line II-II′ of FIG. 6C.

FIG. 6E illustrates a plan view showing a semiconductor package according to some embodiments.

FIG. 7A illustrates a plan view showing a semiconductor package according to some embodiments.

FIG. 7B illustrates a cross-sectional view taken along line IV-IV′ of FIG. 7A.

FIG. 7C illustrates a cross-sectional view taken along line IV-IV′ of FIG. 7A.

FIGS. 8A to 8M illustrate cross-sectional views showing a method of fabricating a semiconductor package according to some embodiments.

### DETAILED DESCRIPTION OF EMBODIMENTS

In this description, like reference numerals may indicate like components. The following will now describe a semiconductor package and its fabrication method according to the present inventive concepts.

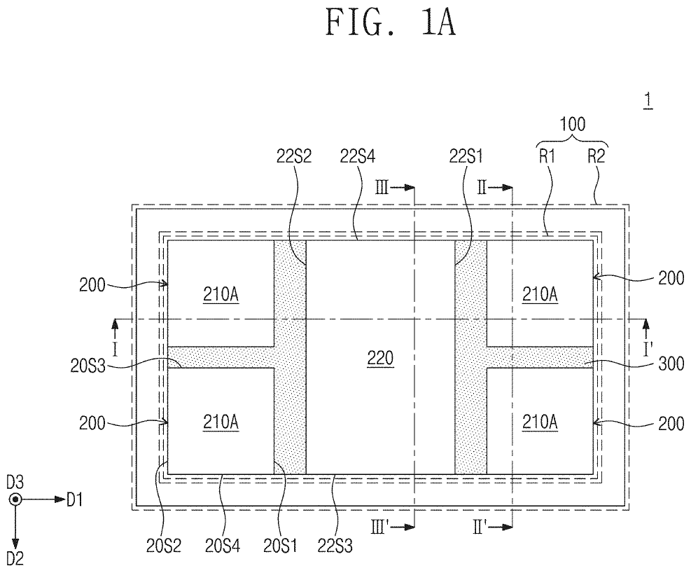

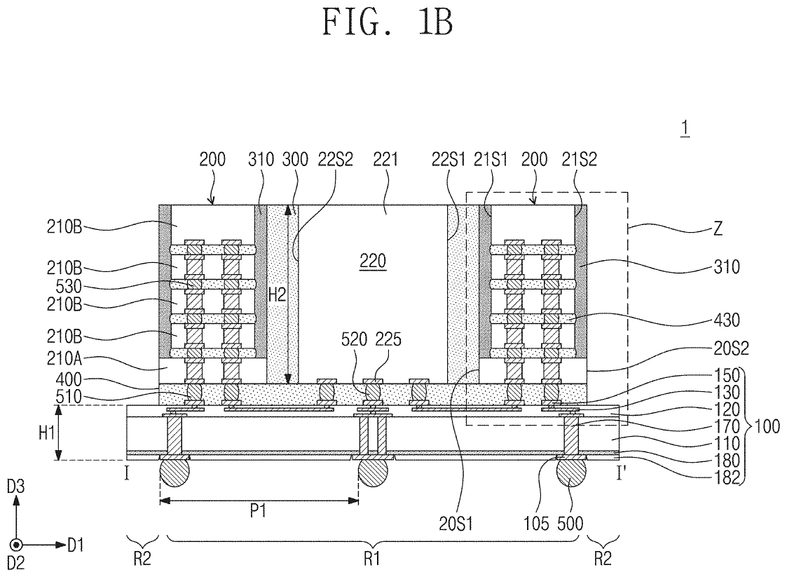

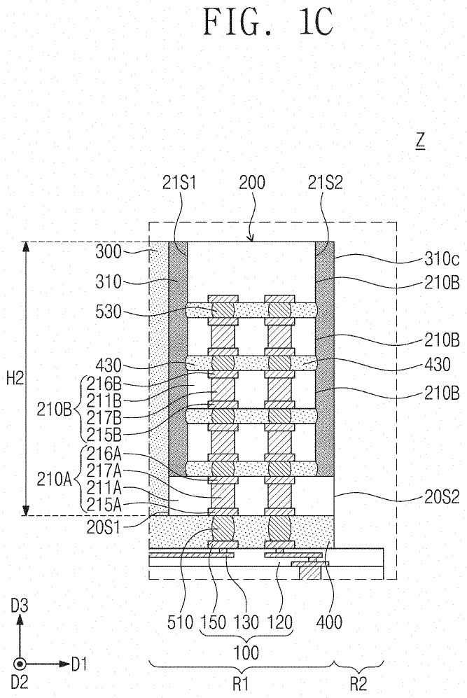

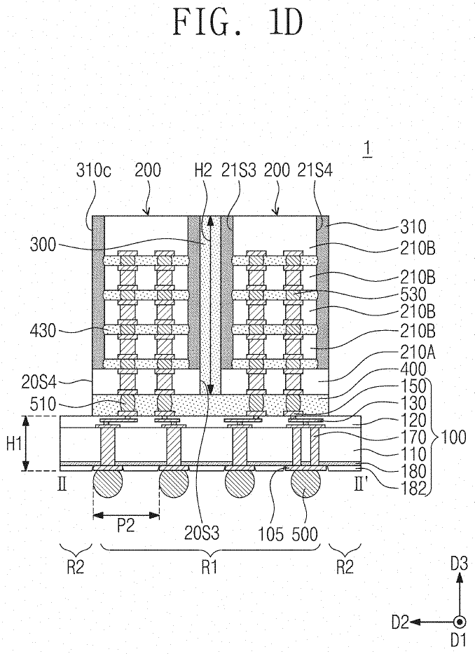

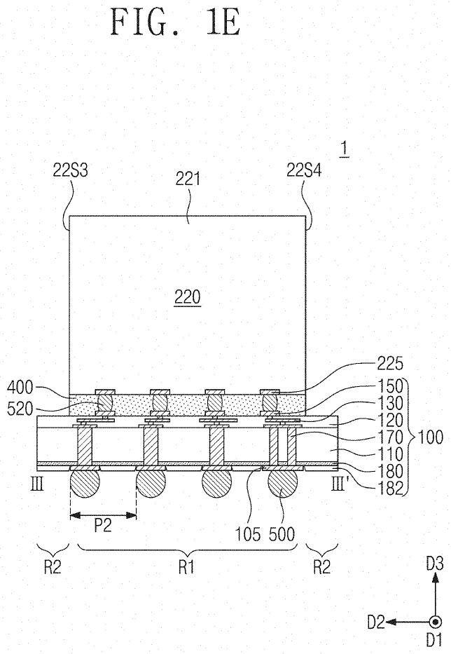

FIG. 1A illustrates a plan view showing a semiconductor package according to some embodiments. FIG. 1B illustrates a cross-sectional view taken along line I-I′ of FIG. 1A. FIG. 1C illustrates an enlarged view showing section Z of FIG. 1B. FIG. 1D illustrates a cross-sectional view taken along line II-II′ of FIG. 1A. FIG. 1E illustrates a cross-sectional view taken along line of FIG. 1A.

Referring to FIGS. 1A to 1C, a semiconductor package may include a first package 1. The first package 1 may include connection solders 500, a substrate, a chip stack 200, a second semiconductor chip 220, and a molding layer 300. The first package 1 may include first bumps 510, second bumps 520, and an under-fill layer 400.

The substrate may be an interposer substrate 100. The interposer substrate 100 may include a semiconductor die 110, through vias 170, a dielectric layer 120, wiring structures 130, and interposer pads 150. The interposer substrate 100 may not include an integrated circuit such as transistors. The interposer substrate 100 may have a height H1 of about 150 μm to about 150 μm. The semiconductor die 110 may have a relatively low coefficient of thermal expansion (CTE). For example, the coefficient of thermal expansion of the semiconductor die 110 may range from about 3.2 ppm/° C. to about 4.2 ppm/° C. The semiconductor die 110 may include a silicon die, a germanium die, or a silicon-germanium die. The semiconductor die 110 may have a top surface and a bottom surface that are opposite to each other.

A first direction D1 may be parallel to a bottom surface of the interposer substrate 100. A second direction D2 may be substantially orthogonal to the first direction D1 while being parallel to the bottom surface of the interposer substrate 100. A third direction D3 may be substantially perpendicular to the first direction D1 and the second direction D2.

The through vias 170 may be provided in the semiconductor die 110. The through vias 170 may include a conductive material, such as metal. The through vias 170 may be laterally spaced apart from each other. The through vias 170 may penetrate the top and bottom surfaces of the semiconductor die 110.

A wiring layer may be provided on the top surface of the semiconductor die 110. The wiring layer may include the dielectric layer 120 and the wiring structures 130. The dielectric layer 120 may include a plurality of layers. The dielectric layer 120 may include a silicon-based dielectric material, such as one or more of silicon oxide, silicon nitride, silicon oxynitride, and tetraethylorthosilicate (TEOS). The wiring structures 130 may be provided in the dielectric layer 120. The wiring structures 130 may include conductive lines and conductive vias. The conductive lines may have their major axes that are parallel to the first direction D1 or the second direction D2. The conductive vias may have their major axes that are substantially parallel to each other. The conductive vias may be connected to the conductive lines. The wiring structures 130 may include metal, such as one or more of copper, tungsten, titanium, and any alloy thereof.

The interposer pads 150 may be provided on a top surface of the interposer substrate 100. For example, the interposer pads 150 may be provided on and coupled to the wiring structures 130. The wiring structures 130 may include a first wiring structure and a second wiring structure. The second wiring structure may be electrically separated from the first wiring structure. Two interposer pads 150 may be electrically connected to each other through the first wiring structure. Another of the interposer pads 150 may be electrically connected through the second wiring structure to one of the through vias 170. The phrase “electrically connected to the interposer substrate 100” may mean the meaning that “electrically connected to at least one of the wiring structures 130.” The phrase “two components are electrically connected/coupled to each other” may include the meaning that the two components are connected/coupled directly to each other or indirectly to each other through other conductive component(s).

The connection solders 500 may be provided on the bottom surface of the interposer substrate 100 and may be coupled to the through vias 170. The connection solders 500 may be laterally spaced apart and electrically separated from each other. The connection solders 500 may include solder balls. The solder balls may include, for example, one or more of tin (Sn), silver (Ag), zinc (Zn), and any alloy thereof. The first package 1 may further include solder pads 105. The solder pads 105 may be interposed between the connection solders 500 and the through vias 170. The solder pads 105 may include a different material from that of the solder balls. The solder pads 105 may include metal, such as copper, gold, or nickel.

One of the connection solders 500 may be electrically connected to a plurality of through vias 170. For example, two through vias 170 may be interposed between one of the solder pads 105 and its corresponding wiring structure 130. The one solder pad 105 may be coupled through the two through vias 170 to the wiring structure 130. Even when failure occurs in one of the two through vias 170, the solder pad 105 may be electrically connected to the wiring structure 130 through the other of the two through vias 170. Therefore, the interposer substrate 100 may increase in reliability of electrical connection.

The interposer substrate 100 may further include a first passivation pattern 180 and a second passivation pattern 182. The first passivation pattern 180 may be provided on the bottom surface of the interposer substrate 100 to cover the bottom surface of the semiconductor die 110. The first passivation pattern 180 may further cover lower sidewalls of the through vias 170. The first passivation pattern 180 may have a bottom surface located at substantially the same level as that of bottom surfaces of the through vias 170. The first passivation pattern 180 may have outer sidewalls that are vertically aligned with those of the semiconductor die 110. The term “vertical” may indicate the meaning that “parallel to the third direction D3.” The first passivation pattern 180 may include a dielectric material, such as silicon nitride.

The second passivation pattern 182 may be provided on and cover the bottom surface of the first passivation pattern 180. The second passivation pattern 182 may have outer sidewalls that are vertically aligned with those of the first passivation pattern 180 and those of the semiconductor die 110. The second passivation pattern 182 may include a different material from that of the first passivation pattern 180. The second passivation pattern 182 may include an organic dielectric material, such as photosensitive polyimide (PSPI). The first and second passivation patterns 180 and 182 may protect the interposer substrate 100. The bottom surface of the interposer substrate 100 may include a bottom surface of the second passivation pattern 182.

The interposer substrate 100 may have a central region R1 and an edge region R2 when viewed in plan. When viewed in plan, the edge region R2 of the interposer substrate 100 may be provided between the central region R1 of the interposer substrate 100 and sidewalls of the interposer substrate 100. The edge region R2 of the interposer substrate 100 may surround the central region R1 of the interposer substrate 100.

The chip stack 200 may be provided on a top surface at the central region R1 of the interposer substrate 100. The chip stack 200 may be provided in plural. Each of the plurality of chip stacks 200 may include a first lower semiconductor chip 210A and one or more first upper semiconductor chips 210B.

The first lower semiconductor chip 210A may be a logic chip or a controller chip. For example, the first lower semiconductor chip 210A may control the first upper semiconductor chips 210B. Alternatively, the first lower semiconductor chip 210A may be a memory chip.

The first lower semiconductor chip 210A may have a first sidewall 20S1, a second sidewall 20S2, a third sidewall 20S3, and a fourth sidewall 20S4. The first sidewall 20S1 of the first lower semiconductor chip 210A may face the second semiconductor chip 220. The second sidewall 20S2 of the first lower semiconductor chip 210A may stand opposite to the first sidewall 20S1 of the first lower semiconductor chip 210A. The third sidewall 20S3 of the first lower semiconductor chip 210A may neighbor the first sidewall 20S1 and the second sidewall 20S2 of the first lower semiconductor chip 210A. The third sidewall 20S3 of the first lower semiconductor chip 210A may face a neighboring chip stack 200. The fourth sidewall 20S4 of the first lower semiconductor chip 210A may stand opposite to the third sidewall 20S3 of the first lower semiconductor chip 210A. The fourth sidewall 20S4 of the first lower semiconductor chip 210A may neighbor the first sidewall 20S1 and the second sidewall 20S2 of the first lower semiconductor chip 210A.

As shown in FIG. 1C, the first lower semiconductor chip 210A may include a first semiconductor die 211A, first integrated circuits (not shown), first lower pads 215A, first conductive vias 217A, and first upper pads 216A. The first semiconductor die 211A may have a relatively low coefficient of thermal expansion (CTE). For example, the coefficient of thermal expansion of the first semiconductor die 211A may range from about 3.2 ppm/° C. to about 4.2 ppm/° C. The first semiconductor die 211A may include a silicon die, a germanium die, or a silicon-germanium die. The first integrated circuits of the first lower semiconductor chip 210A may be provided in the first lower semiconductor chip 210A. The first lower pads 215A may be provided on a bottom surface of the first semiconductor die 211A. The first lower pads 215A may be electrically connected to the first integrated circuits.

The first conductive vias 217A may be provided in the first semiconductor die 211A of the first lower semiconductor chip 210A. The first conductive vias 217A may be coupled to the first lower pads 215A and at least one of the first integrated circuits. The first upper pads 216A may be provided on a top surface of the first semiconductor die 211A and may be coupled to the first conductive vias 217A. Each of the first lower semiconductor chips 210A may further include first redistribution lines (not shown) provided between the first upper pads 216A and the first conductive vias 217A. The first upper pads 216A may be coupled through the first redistribution lines to the first conductive vias 217A.

When viewed in plan, the first lower pads 215A, the first conductive vias 217A, and the first upper pads 216A may be disposed on a central region of the first lower semiconductor chip 210A, but the present inventive concepts are not limited thereto. The first lower pads 215A and the first upper pads 216A may be conductive pads. The first lower pads 215A, the first conductive vias 217A, and the first upper pads 216A may include, for example, metal.

The first upper semiconductor chip 210B may be provided on the first lower semiconductor chip 210A. Each of the chip stacks 200 may include a plurality of first upper semiconductor chips 210B. The first upper semiconductor chips 210B may be vertically stacked on each other. The first upper semiconductor chips 210B may be of a different type from the first lower semiconductor chip 210A. For example, the first upper semiconductor chips 210B may be memory chips. The memory chips may include high bandwidth memory (HBM) chips. Alternatively, the first upper semiconductor chips 210B may be of the same type as the first lower semiconductor chip 210A. For example, the first upper semiconductor chips 210B may be logic chips. The first upper semiconductor chips 210B may have their widths less than that of the first lower semiconductor chip 210A.

Each of the first upper semiconductor chips 210B may have a first lateral surface 21S1 and a second lateral surface 21S2. The first lateral surface 21S1 of each of the first upper semiconductor chips 210B may face the second semiconductor chip 220. The second lateral surface 21S2 of each of the first upper semiconductor chips 210B may stand opposite to the first lateral surface 21S1 of each of the first upper semiconductor chips 210B.

Each of the first upper semiconductor chips 210B may include a second semiconductor die 211B, second integrated circuits (not shown), second lower pads 215B, second conductive vias 217B, and second upper pads 216B. The second integrated circuits may be provided in each of the first upper semiconductor chips 210B. The second lower pads 215B and the second upper pads 216B may be respectively provided on bottom surfaces and top surfaces of the first upper semiconductor chips 210B. The second lower pads 215B and the second upper pads 216B may have correspondingly have electrical connection with the second integrated circuits of the first upper semiconductor chip 210B. The second conductive vias 217B may be disposed in and penetrate the second semiconductor die 211B. The second conductive vias 217B may be coupled to the second lower pads 215B and the second upper pads 216B. The second conductive vias 217B may further be coupled to the second integrated circuits. Each of the first upper semiconductor chips 210B may further include second redistribution lines (not shown) provided between the second upper pads 216B and the second conductive vias 217B. The second upper pads 216B may be coupled through the second redistribution lines to the second conductive vias 217B.

An uppermost first upper semiconductor chip 210B may include the second semiconductor die 211B, the second integrated circuits, and the second lower pads 215B, but may not include the second conductive vias 217B or the second upper pads 216B. The uppermost first upper semiconductor chip 210B may have a thickness greater than those of other first upper semiconductor chips 210B.

When viewed in plan, the second lower pads 215B, the second conductive vias 217B, and the second upper pads 216B may be provided on a central region of the first upper semiconductor chip 210B that corresponds thereto. Differently from that shown, one or more of the second lower pads 215B, the second conductive vias 217B, and the second upper pads 216B may be provided on an edge region of the first upper semiconductor chip 210B that corresponds thereto.

Each of the chip stacks 200 may further include conductive bumps 530. The conductive bumps 530 may be interposed between the first upper semiconductor chips 210B. The conductive bumps 530 may be coupled to the second lower pads 215B and the second upper pads 216B that face each other. The conductive bumps 530 may further be interposed between the first lower semiconductor chip 210A and a lowermost first upper semiconductor chip 210B, and may be coupled to the first upper pads 216A and the second lower pads 215B of the lowermost first upper semiconductor chip 210B. The first upper semiconductor chips 210B may be electrically connected through the conductive bumps to the first lower semiconductor chip 210A and the interposer substrate 100. When viewed in plan, the conductive bumps 530 may vertically overlap the central regions of the first upper semiconductor chips 210B, but the present inventive concepts are not limited thereto.

As shown in FIG. 1B, a pitch in the first direction D1 between the conductive bumps 530 may be less than a pitch P1 in the first direction D1 between the connection solders 500. As shown in FIGS. 1D and 1E, a pitch in the second direction D2 between the conductive bumps 530 may be less than a pitch P2 in the second direction D2 between the connection solders 500. Each of the conductive bumps 530 may include a solder material. The conductive bumps 530 may further include pillar patterns (not shown).

Alternatively, the conductive bumps 530 may be omitted. In this case, the second lower pads 215B of one first upper semiconductor chip 210B may be directly bonded to the second upper pads 216B of another first upper semiconductor chip 210B adjacent to the one first upper semiconductor chip 210B. The first lower semiconductor chip 210A may be directly bonded to the lowermost first upper semiconductor chip 210B.

Each of the chip stacks 200 may further include under-fill patterns 430. The under-fill patterns 430 may be provided in a first upper gap between the first lower semiconductor chip 210A and the lowermost first upper semiconductor chip 210B and in second upper gaps between the first upper semiconductor chips 210B. Each of the under-fill patterns 430 may encapsulate corresponding conductive bumps 530. The under-fill patterns 430 may include a dielectric polymer, such as an epoxy-based polymer.

The second semiconductor chip 220 may be provided on the top surface at the central region R1 of the interposer substrate 100. When viewed in plan, the second semiconductor chip 220 may be located between the chip stacks 200. For example, the second semiconductor chip 220 may be disposed laterally spaced apart from the first lower semiconductor chip 210A and the first upper semiconductor chips 210B. The phrase “two components are laterally spaced apart from each other” may mean that “two components are horizontally spaced apart from each other.” The language “horizontal” may indicate the meaning that “parallel to the first direction D1 or the second direction D2.” The second semiconductor chip 220 may be of a different type from the first lower semiconductor chip 210A and the first upper semiconductor chips 210B. The second semiconductor chip 220 may include a logic chip, a buffer chip, or a system-on-chip (SOC). For example, the second semiconductor chip 220 may be a logic chip whose function is different from that of the first lower semiconductor chip 210A. The second semiconductor chip 220 may be, for example, an application specific integrated circuit (ASIC) chip or an application processor (AP) chip. The ASIC chip may include an application specific integrated circuit (ASIC). The second semiconductor chip 220 may include a central processing unit (CPU) or a graphic processing unit (GPU).

The second semiconductor chip 220 may include a third semiconductor die 221, integrated circuits (not shown), and chip pads 225. The integrated circuits may be provided in the second semiconductor chip 220. For example, the integrated circuits of the second semiconductor chip 220 may be disposed on a bottom surface of the third semiconductor die 221. The chip pads 225 may be provided on the bottom surface of the third semiconductor die 221 of the second semiconductor chip 220, and may be electrically connected to the integrated circuits of the second semiconductor chip 220. The number of the chip pads 225 of the second semiconductor chip 220 may be greater than the number of the first lower pads 215A of the first lower semiconductor chip 210A, but the present inventive concepts are not limited thereto.

The second semiconductor chip 220 may have a first sidewall 22S1, a second sidewall 22S2, a third sidewall 22S3, and a fourth sidewall 22S4. The first sidewall 22S1 and the second sidewall 22S2 of the second semiconductor chip 220 may face the chip stacks 200. The second sidewall 22S2 of the second semiconductor chip 220 may stand opposite to the first sidewall 22S1 of the second semiconductor chip 220. The third sidewall 22S3 of the second semiconductor chip 220 may neighbor the first sidewall 22S1 and the second sidewall 22S2 of the second semiconductor chip 220. The fourth sidewall 22S4 of the second semiconductor chip 220 may neighbor the first sidewall 22S1 and the second sidewall 22S2 of the second semiconductor chip 220, and may stand opposite to the third sidewall 22S3 of the second semiconductor chip 220.

Second bumps 520 may be interposed between the interposer substrate 100 and the second semiconductor chip 220. For example, the second bumps 520 may be correspondingly coupled to the interposer pads 150 and the chip pads 225 of the second semiconductor chip 220. The second semiconductor chip 220 may be electrically connected through the interposer substrate 100 to the chip stacks 200 or the connection solders 500. The second bumps 520 may include solder balls. Although not shown, the second bumps 520 may further include pillar patterns. As shown in FIG. 1B, a pitch in the first direction D1 between the second bumps 520 may be less than the pitch P1 in the first direction D1 between the connection solders 500. As shown in FIGS. 1D and 1E, a pitch in the second direction D2 between the second bumps 520 may be less than the pitch P2 in the second direction D2 between the connection solders 500.

As shown in FIG. 1B, the under-fill layer 400 may be provided on bottom surfaces of the chip stacks 200 and a bottom surface of the second semiconductor chip 220. For example, the under-fill layer 400 may be provided in a first gap between the interposer substrate 100 and the first lower semiconductor chip 210A, thereby covering sidewalls of the first bumps 510. The under-fill layer 400 may be provided in a second gap between the interposer substrate 100 and the second semiconductor chip 220, thereby covering sidewalls of the second bumps 520. Therefore, the first lower semiconductor chip 210A and the second semiconductor chip 220 may share the under-fill layer 400. The under-fill layer 400 may have an outer sidewall that is vertically aligned with the second sidewall 20S2 of the first lower semiconductor chip 210A. The under-fill layer 400 may include a dielectric polymer, such as an epoxy-based polymer.

Differently from that shown, a plurality of under-fill layers 400 may be provided on each of the first lower semiconductor chip 210A and the second semiconductor chip 220. The following will describe a single under-fill layer 400.

Each of the chip stacks 200 may further include a molding pattern 310. On a top surface of the first lower semiconductor chip 210A, the molding pattern 310 may cover the first lateral surfaces 21S1 and the second lateral surfaces 21S2 of a plurality of first upper semiconductor chips 210B. The molding pattern 310 may not cover a top surface of the uppermost first upper semiconductor chip 210B. For example, the molding pattern 310 may have a top surface coplanar with that of the uppermost first upper semiconductor chip 210B. The molding pattern 310 may have an outer sidewall 310c that is vertically aligned with the second sidewall 20S2 of the first lower semiconductor chip 210A and with the outer sidewall of the under-fill layer 400. As shown in FIG. 1D, the molding pattern 310 may further cover the third lateral surfaces 21S3 and the fourth lateral surfaces 21S4 of the first upper semiconductor chips 210B. The third lateral surfaces 21S3 of the first upper semiconductor chips 210B may face their neighboring chip stack 200. The third lateral surfaces 21S3 of the first upper semiconductor chips 210B may neighbor the first lateral surfaces 21S1 and the second lateral surfaces 21S2 of the first upper semiconductor chips 210B. The third lateral surfaces 21S3 of the first upper semiconductor chips 210B may stand opposite to the fourth lateral surfaces 21S4 of the first upper semiconductor chips 210B.

The molding pattern 310 may include a first dielectric polymer. The first dielectric polymer may include, for example, an epoxy-based molding compound. For example, the first dielectric polymer may include a different material from that of the under-fill patterns 430. The molding pattern 310 may further include first fillers. The first fillers may be provided in the first dielectric polymer. The first fillers may include an inorganic material, such as silica.

The molding pattern 310 may have a coefficient of thermal expansion greater than that of the first semiconductor die 211A and that of the second semiconductor die 211B. For example, the coefficient of thermal expansion of the molding pattern 310 may range from about 6 ppm/° C. to about 20 ppm/° C. The coefficient of thermal expansion of the molding pattern 310 may be CTE alpha 1. The CTE alpha 1 may be a coefficient of thermal expansion below a glass transition temperature (Tg).

The molding layer 300 may be provided on the interposer substrate 100. For example, the molding layer 300 may be provided on the top surface at the central region R1 of the interposer substrate 100. The molding layer 300 may be provided between the chip stacks 200 and the second semiconductor chip 220 and between the chip stacks 200. For example, the molding layer 300 may be provided between the second semiconductor chip 220 and the first sidewall 20S1 of the first lower semiconductor chip 210A and between the second semiconductor chip 220 and the first lateral surfaces 21S1 of the first upper semiconductor chips 210B. The molding pattern 310 may be interposed between the molding layer 300 and the first lateral surfaces 21S1 of the first upper semiconductor chips 210B.

The molding layer 300 may not be provided on the edge region R2 of the interposer substrate 100. For example, the molding layer 300 may not be provided on the second sidewall 20S2 of the first lower semiconductor chip 210A. The molding layer 300 may externally expose the second sidewall 20S2 of the first lower semiconductor chip 210A. The molding layer 300 may not be provided on the second lateral surfaces 21S2 of the first upper semiconductor chips 210B.

As shown in FIG. 1D, the molding layer 300 may be provided on the third sidewall 20S3 of the first lower semiconductor chip 210A and on the third lateral surfaces 21S3 of the first upper semiconductor chips 210B. The molding pattern 310 may further be interposed between the molding layer 300 and the third lateral surfaces 21S3 of the first upper semiconductor chips 210B. The molding layer 300 may not be provided on the fourth sidewall 20S4 of the first lower semiconductor chip 210A or on the fourth lateral surfaces 21S4 of the first upper semiconductor chips 210B. As shown in FIG. 1E, the molding layer 300 may expose the third sidewall 22S3 and the fourth sidewall 22S4 of the second semiconductor chip 220.

The molding layer 300 may have a top surface located at a higher level than that of the top surface of the first lower semiconductor chip 210A. The top surface of the molding layer 300 may be coplanar with that of the second semiconductor chip 220, that of the molding pattern 310, and that of the uppermost first upper semiconductor chip 210B.

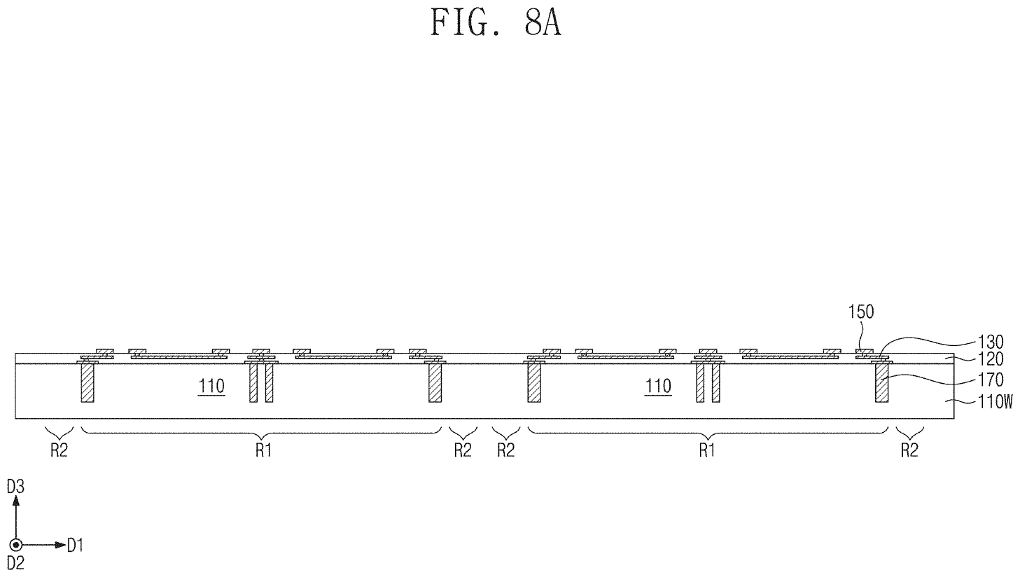

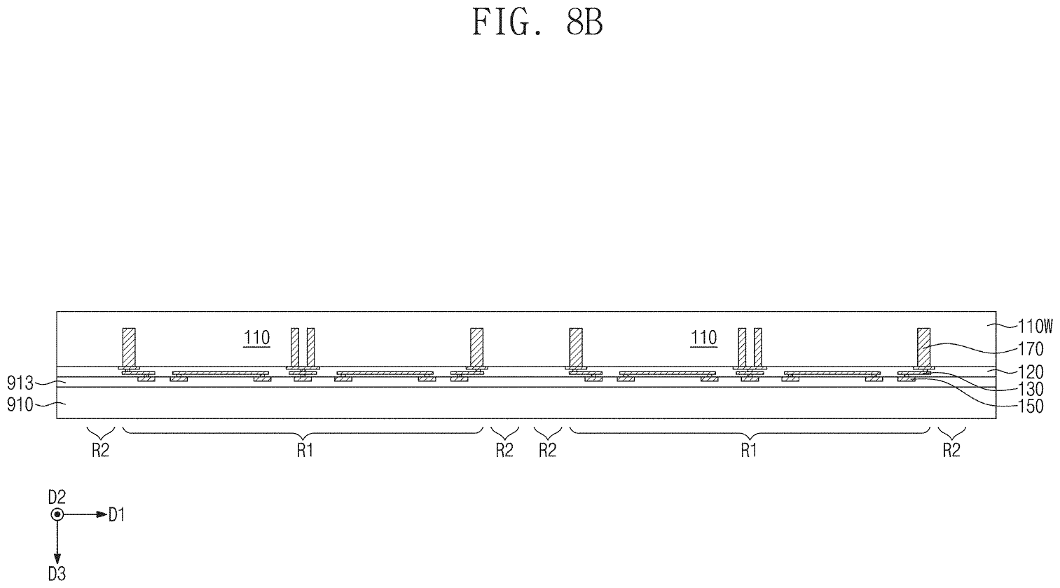

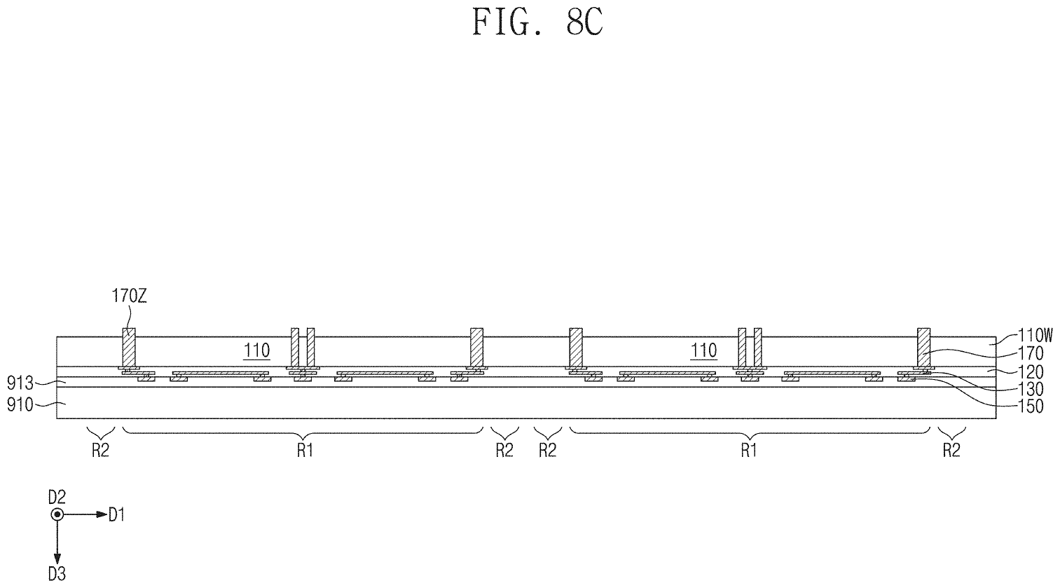

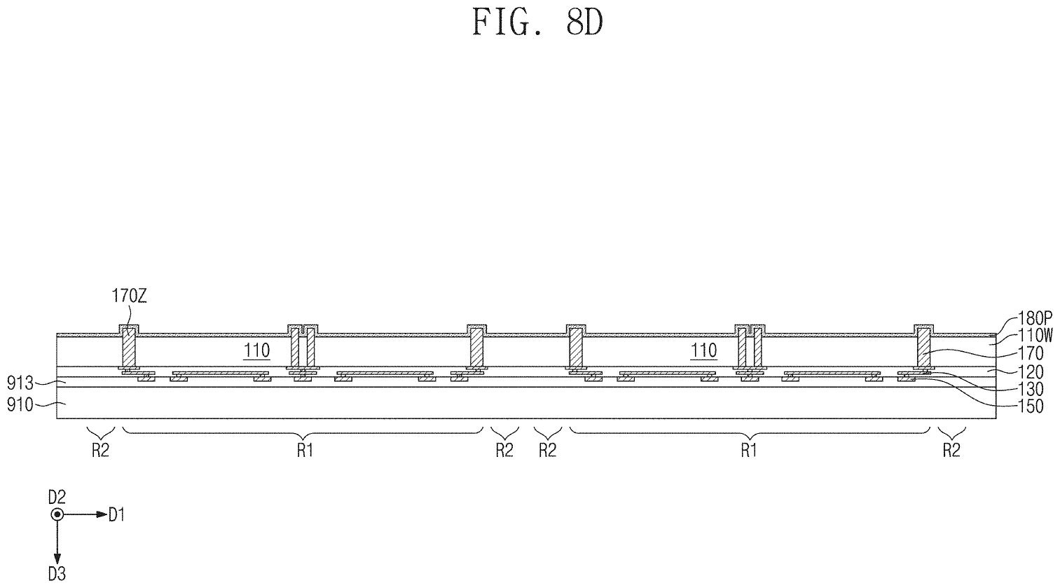

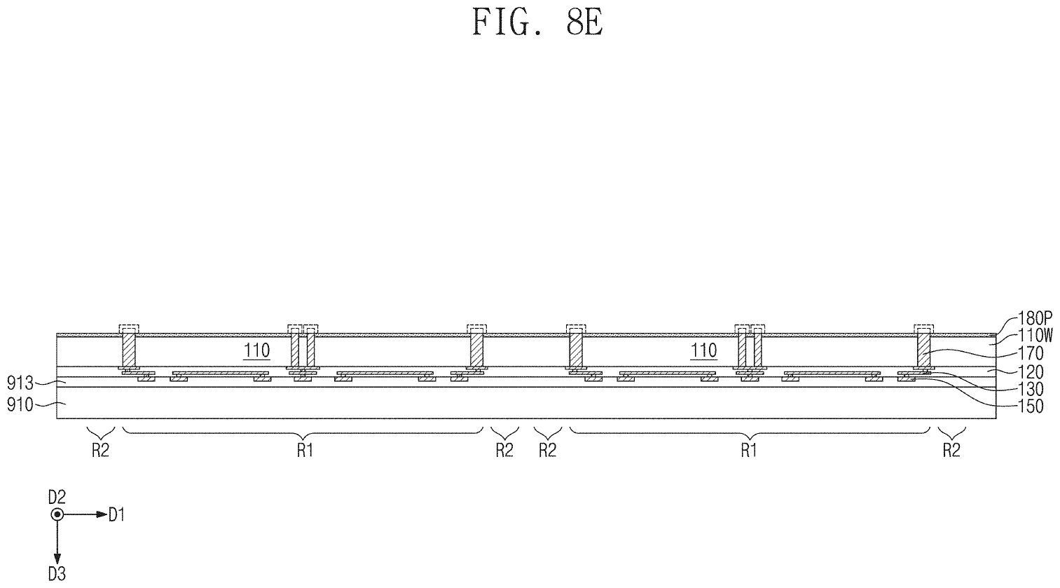

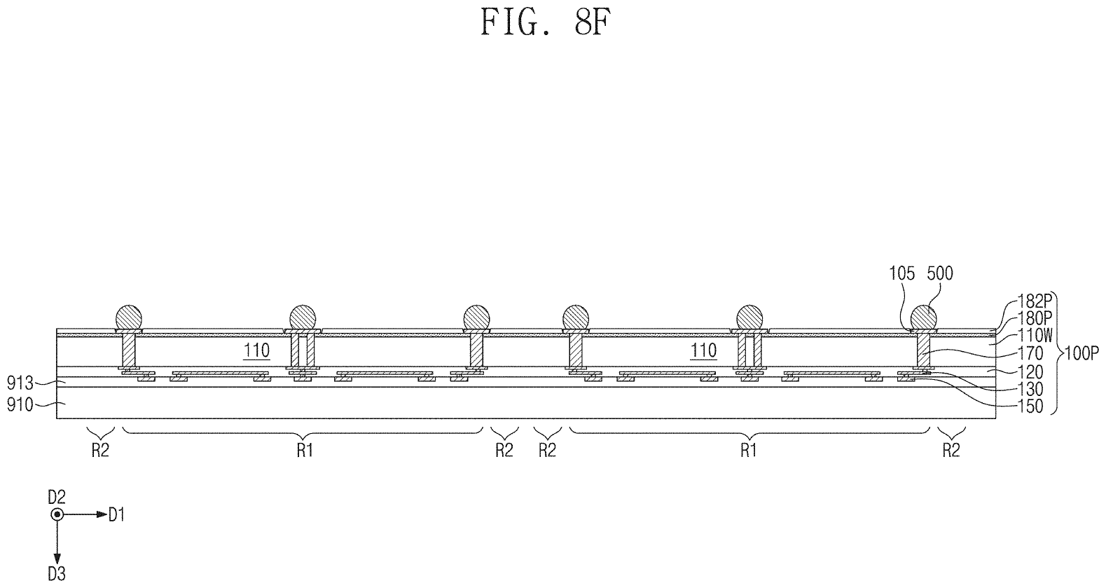

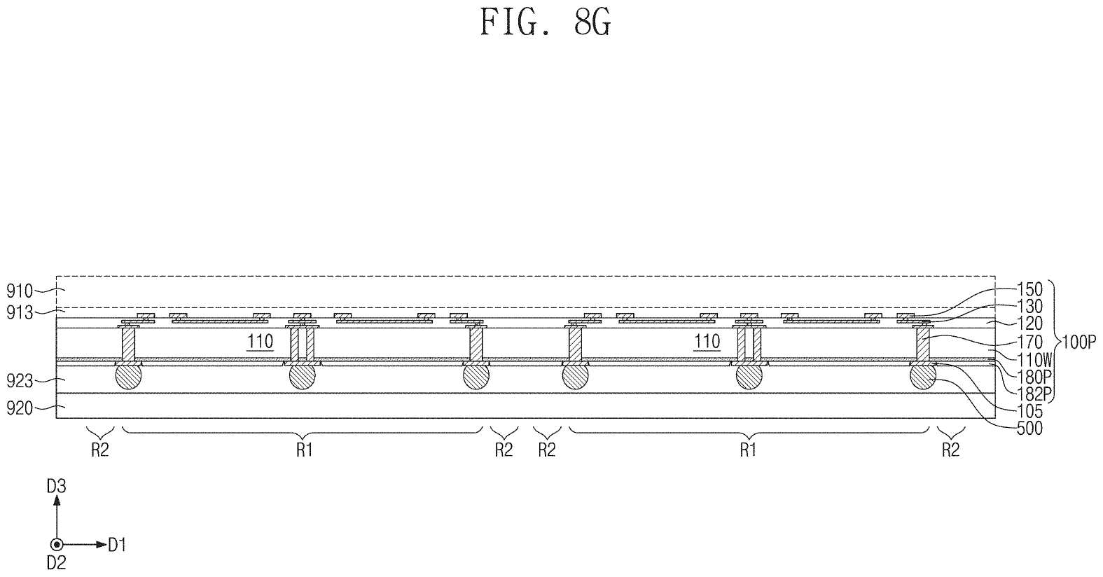

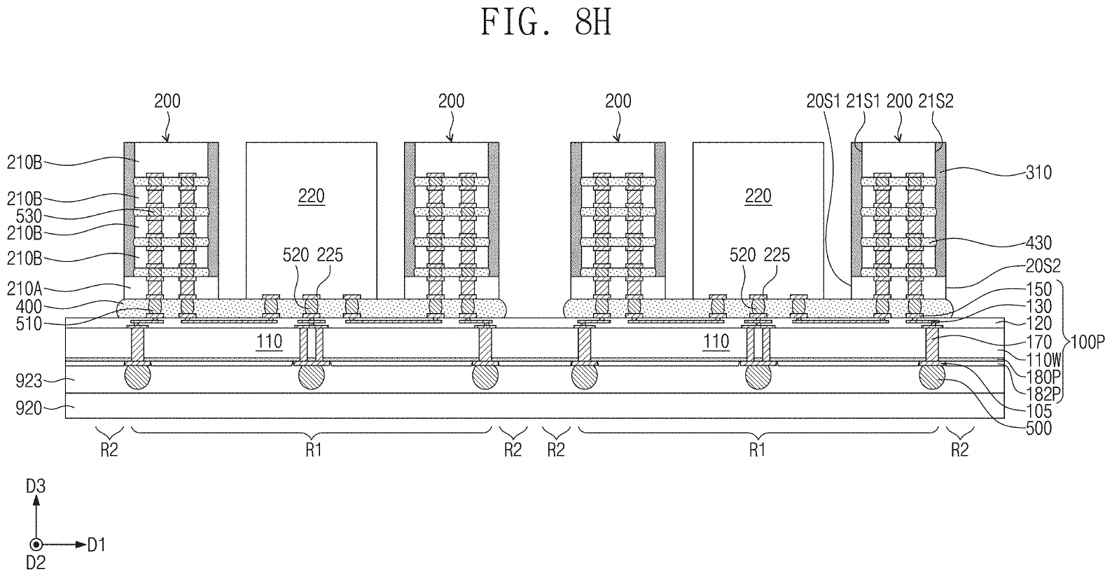

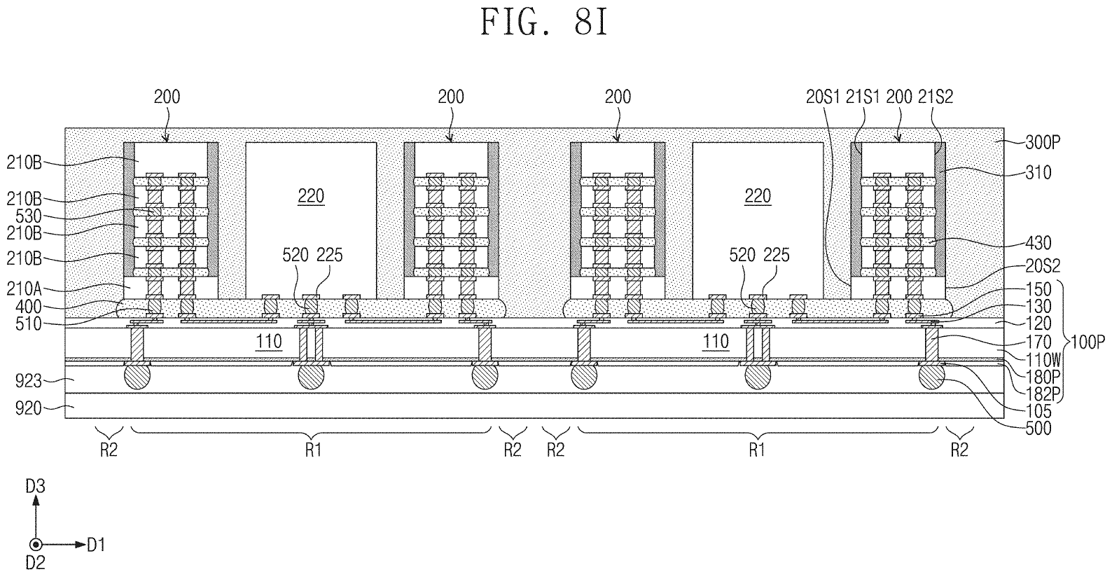

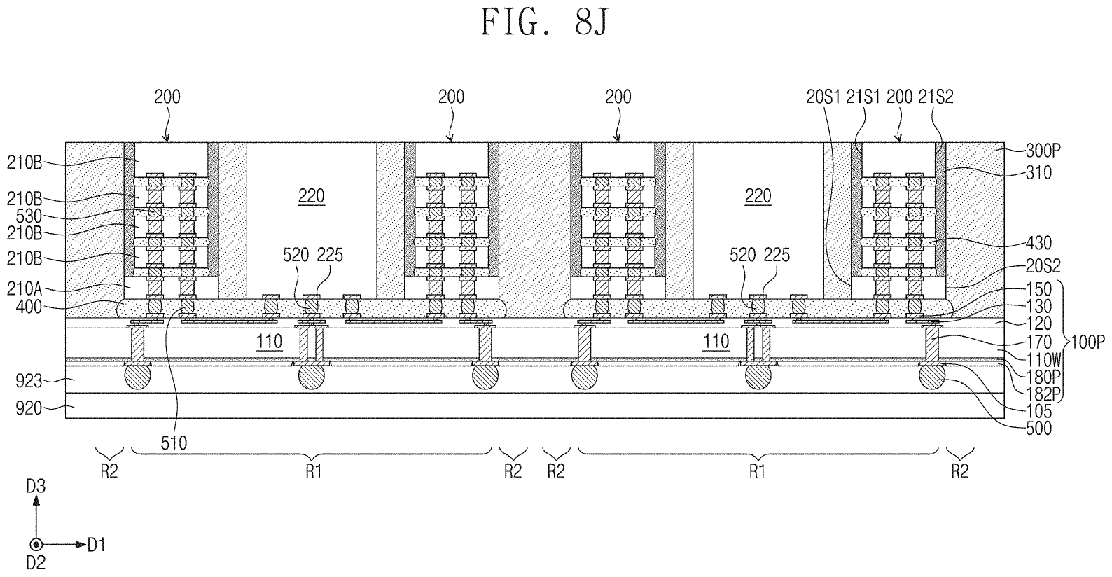

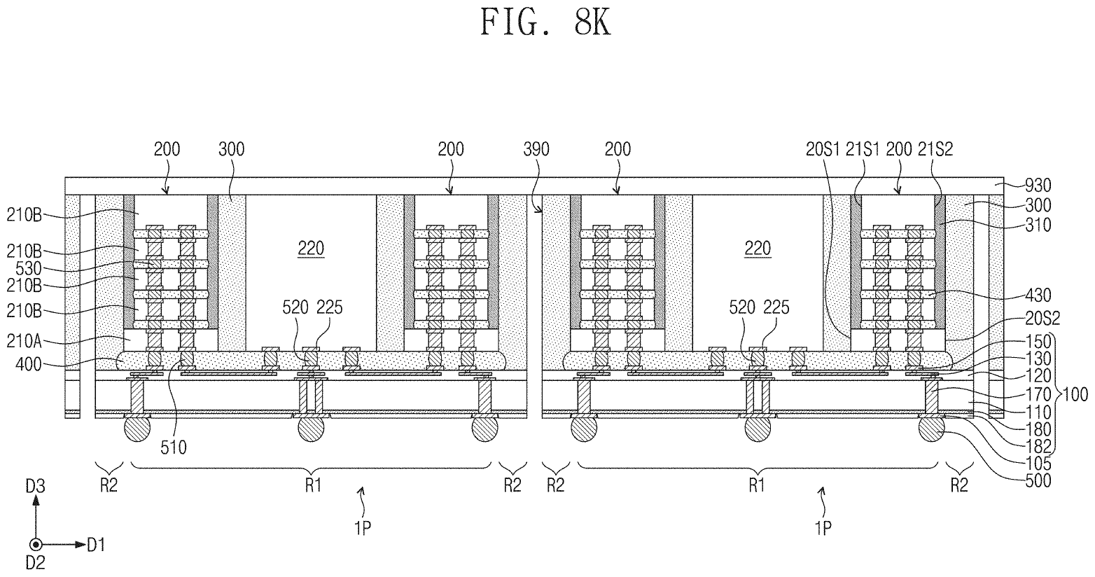

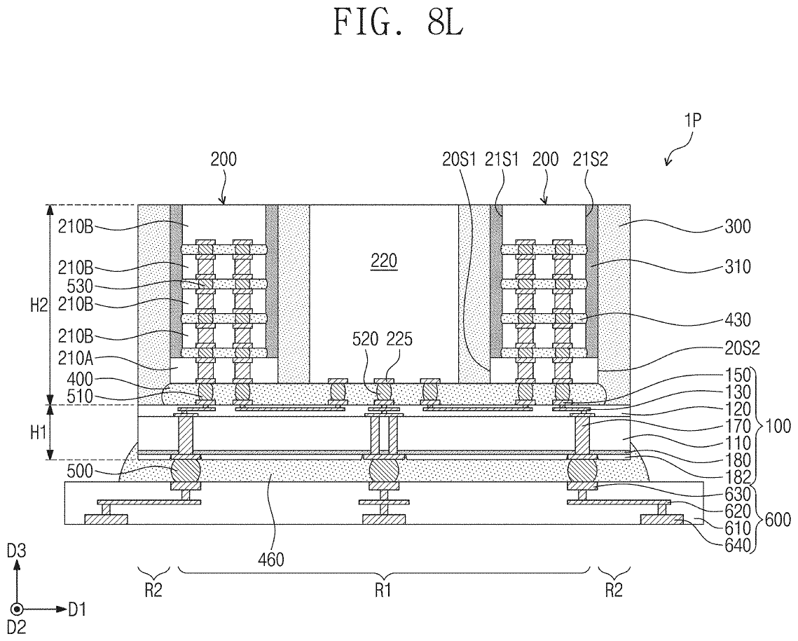

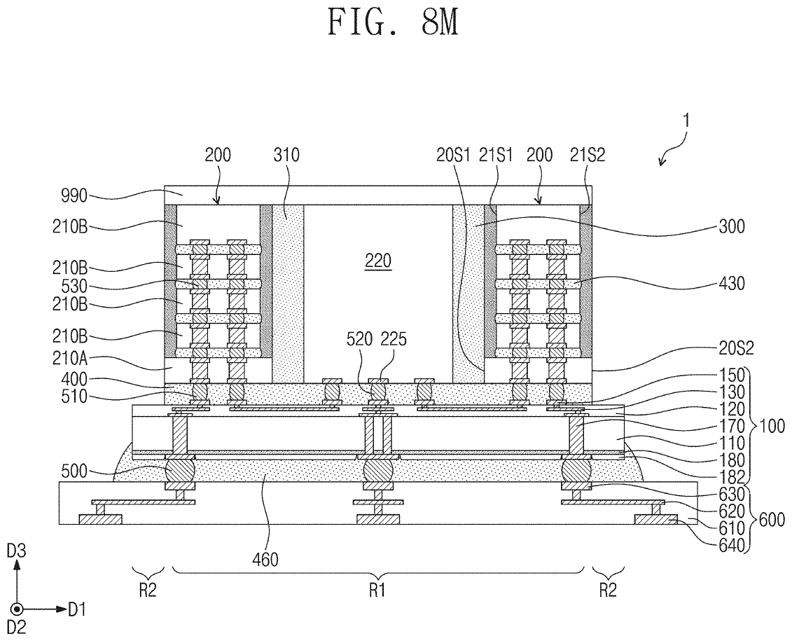

The molding layer 300 may have a coefficient of thermal expansion greater than that of the interposer substrate 100, that of the first lower semiconductor chip 210A, those of the first upper semiconductor chips 210B, and that of the second semiconductor chip 220. For example, the coefficient of thermal expansion of the molding layer 300 may be greater than that of the semiconductor die 110, that of the first semiconductor die 211A, that of the second semiconductor die 211B, and that of the third semiconductor die 221. For example, the coefficient of thermal expansion of the molding layer 300 may range from about 6 ppm/° C. to about 20 ppm/° C. The coefficient of thermal expansion of the molding layer 300 may be CTE alpha 1. When the molding layer 300 covers sidewalls of the first lower semiconductor chip 210A, the first lower semiconductor chip 210A may experience stress caused by a difference in coefficient of thermal expansion between the molding layer 300 and the first semiconductor die 211A. The stress may occur under a condition at relatively high temperatures. For example, the stress may occur in a mounting process which will be discussed in FIG. 8L. The stress may be concentrated on the edge region R2 of the first lower semiconductor chip 210A. The stress may induce the occurrence of a crack between the molding layer 300 and the first lower semiconductor chip 210A. The crack may cause the molding layer 300 to delaminate from the first sidewall 20S1 of the first lower semiconductor chip 210A. The crack may propagate onto a bottom surface of the first lower semiconductor chip 210A and may then be transferred to the first bumps 510. In this case, the first bumps 510 may be damaged. A poor electrical connection may be provided between the interposer substrate 100 and the first lower semiconductor chip 210A.

According to some embodiments, the second sidewall 20S2 and the third sidewall 20S3 of the first lower semiconductor chip 210A may not be covered with but may be externally exposed by the molding layer 300. For example, the second sidewall 20S2 and the third sidewall 20S3 of the first lower semiconductor chip 210A may be in contact with air of an external space. Therefore, the occurrence of a crack may be prevented or reduced between the molding layer 300 and the first lower semiconductor chip 210A. Accordingly, the first bumps 510 may be prevented or reduced from damage, and a semiconductor package may increase in reliability.

The molding layer 300 may include a second dielectric polymer. The second dielectric polymer may include, for example, an epoxy-based molding compound. The second dielectric polymer may include a different material from that of the under-fill patterns 430. The molding layer 300 may further include second fillers. The molding layer 300 may include the same material as that of the molding pattern 310. For example, the second dielectric polymer may be the same as the first dielectric polymer. For another example, the molding layer 300 may include a different material from that of the molding pattern 310. In this case, the second dielectric polymer may be different from the first dielectric polymer. Alternatively, the second fillers may be different from the first fillers. For example, the second fillers may differ from the first fillers in terms of material, shape, or content ratio.

The molding layer 300 may be provided between the chip stacks 200 and the second semiconductor chip 220 and between the chip stacks 200, and thus a semiconductor package may be prevented or reduced from warpage. For example, the interposer substrate 100 may have a relatively small thickness. When the molding layer 300 is omitted, the interposer substrate 100 may experience warpage. In this case, a poor electrical connection may be provided between the interposer substrate 100 and the chip stacks 200 and between the interposer substrate 100 and the second semiconductor chip 220.

The molding layer 300 may have a first height H2. The first height H2 may be a height at the central region R1 of the interposer substrate 100. According to some embodiments, the first height H2 may be greater than the height H1 of the interposer substrate 100. For example, the first height H2 may range from about 300 μm to about 1,000 μm. Therefore, the molding layer 300 may physically hold the interposer substrate 100 to prevent or reduce warpage of the interposer substrate 100. A semiconductor package may exhibit improved reliability.

When the first height H2 is less than about 300 μm or smaller than 5 times the height H1 of the interposer substrate 100, the interposer substrate 100 may experience warpage. When the first height H2 is greater than about 1,000 μm or larger than about 10 times the height H1 of the interposer substrate 100, it may be difficult to achieve compactness of a semiconductor package. According to some embodiments, the first height H2 may be about 5 times to about 10 times the height H1 of the interposer substrate 100. Accordingly, the interposer substrate 100 may be prevented or reduced from warpage, and a semiconductor package may be easy to become compact-sized.

In figures other than FIGS. 1B to 1D, for brevity of drawing, there is no illustration of the first semiconductor die 211A, the second semiconductor die 211B, or the third semiconductor die 221, but the present inventive concepts do not intend to exclude the first semiconductor die 211A, the second semiconductor die 211B, or the third semiconductor die 221.

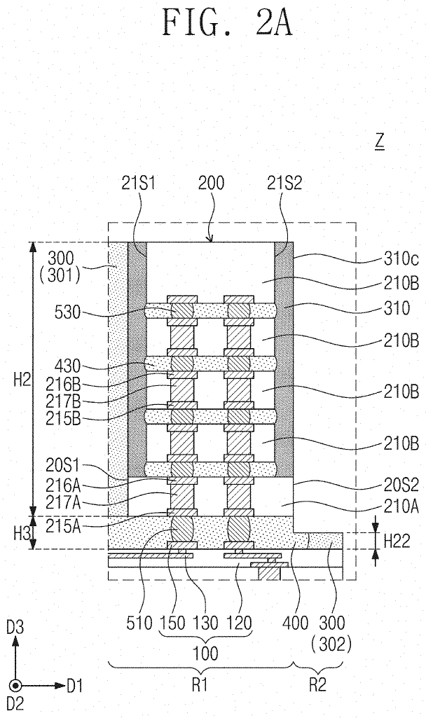

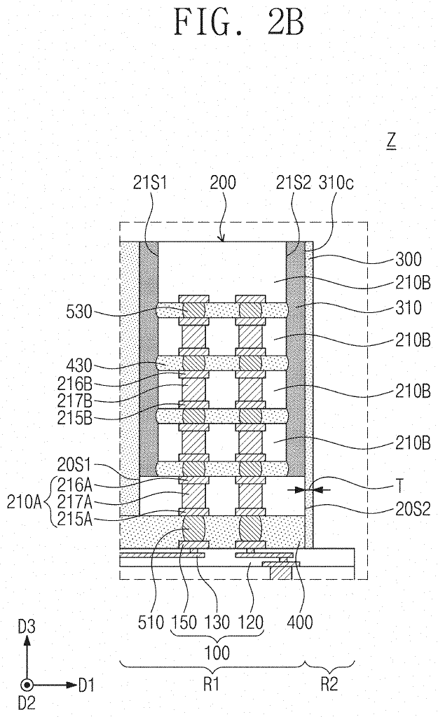

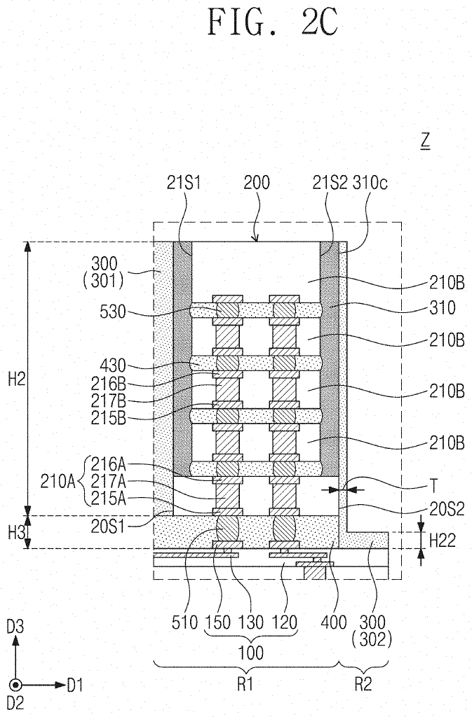

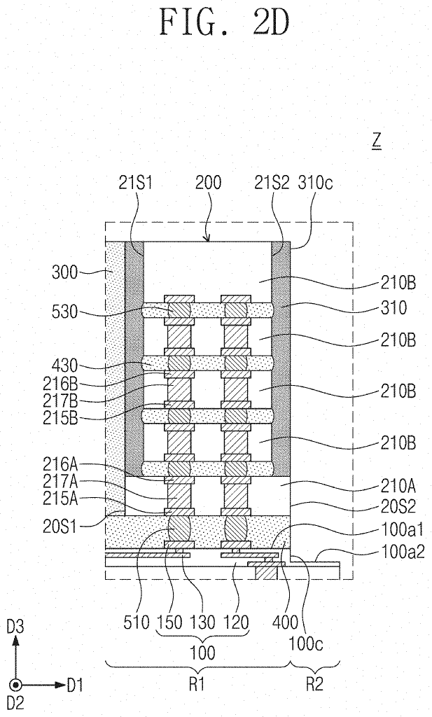

The following will describe in detail a molding layer according to some embodiments. FIGS. 1A and 1B will also be referred to hereinafter in explaining the embodiments of FIGS. 2A to 2D.

FIG. 2A illustrates an enlarged cross-sectional view of section Z depicted in FIG. 1B, showing a molding layer according to some embodiments.

Referring to FIG. 2A, the molding layer 300 may include a first part 301 and a second part 302. The first part 301 of the molding layer 300 may be substantially the same as the molding layer 300 of FIGS. 1A to 1E. For example, the first part 301 of the molding layer 300 may be provided on the central region R1 of the interposer substrate 100 and disposed between the chip stacks 200 and the second semiconductor chip 220. The molding layer 300 may have the first height H2 discussed in FIGS. 1A to 1D.

The second part 302 of the molding layer 300 may be provided on the edge region R2 of the interposer substrate 100 and may cover the top surface at the edge region R2 of the interposer substrate 100. When viewed in plan, the second part 302 of the molding layer 300 may be provided between the second sidewall 20S2 of the first lower semiconductor chip 210A and the sidewall of the interposer substrate 100. The second part 302 of the molding layer 300 may have a second height H22.

The second height H22 may be less than the first height H1 of the molding layer 300. The second height H22 may be less than heights H3 of the first bumps 510. The second part 302 of the molding layer 300 may have a top surface located at a lower level than that of top surfaces of the first bumps 510. Therefore, the molding layer 300 may not cover the second sidewall 20S2 of the first lower semiconductor chip 210A. The second part 302 of the molding layer 300 may be spaced apart from the first lower semiconductor chip 210A. Therefore, no crack may occur between the first lower semiconductor chip 210A and the second part 302 of the molding layer 300. The under-fill layer 400 on the edge region R2 of the interposer substrate 100 may be substantially the same as the second height H22. The height of the under-fill layer 400 on the edge region R2 of the interposer substrate 100 may be less than that of the under-fill layer 400 on the bottom surface of the first lower semiconductor chip 210A.

FIG. 2B illustrates an enlarged cross-sectional view of section Z depicted in FIG. 1B, showing a molding layer according to some embodiments.

Referring to FIG. 2B, on the edge region R2 on the top surface of the interposer substrate 100, the molding layer 300 may further be provided on the second sidewall 20S2 of the first lower semiconductor chip 210A. The molding layer 300 may have a small thickness T on the second sidewall 20S2 of the first lower semiconductor chip 210A. For example, a value of equal to or less than about 200 μm may be given to the thickness T of the molding layer 300 on the second sidewall 20S2 of the first lower semiconductor chip 210A. For example, a range of about 0.00001 μm to about 200 μm may be given to the thickness T of the molding layer 300 on the second sidewall 20S2 of the first lower semiconductor chip 210A. Therefore, even when the molding layer 300 is provided on the second sidewall 20S2 of the first lower semiconductor chip 210A, the occurrence of a crack may be reduced or prevented between the molding layer 300 and the first lower semiconductor chip 210A.

The molding layer 300 may further be provided on the second lateral surfaces 21S2 of the first upper semiconductor chips 210B, thereby covering the outer sidewall 310c of the molding pattern 310. A value of equal to or less than about 200 μm may be given to a thickness of the molding layer 300 on the second lateral surfaces 21S2 of the first upper semiconductor chips 210B. For example, a range of about 0.00001 μm to about 200 μm may be given to the thickness of the molding layer 300 on the second lateral surfaces 21S2 of the first upper semiconductor chip 210B.

FIG. 2C illustrates an enlarged cross-sectional view of section Z depicted in FIG. 1B, showing a molding layer according to some embodiments.

Referring to FIG. 2C, the molding layer 300 may include a first part 301 and a second part 302. The second part 302 of the molding layer 300 may be the same as or similar to that discussed above in the embodiment of FIG. 2A. In contrast, the second part 302 of the molding layer 300 may further cover the second sidewall 20S2 of the first lower semiconductor chip 210A. For example, a value of equal to or less than about 200 μm may be given to a thickness T of the molding layer 300 on the second sidewall 20S2 of the first lower semiconductor chip 210A. For example, a range of about 0.00001 μm to about 200 μm may be given to the thickness T of the molding layer 300 on the second sidewall 20S2 of the first lower semiconductor chip 210A.

The molding layer 300 may further extend onto the second lateral surfaces 21S2 of the first upper semiconductor chips 210B, thereby covering the outer sidewall 310c of the molding pattern 310. A value of equal to or less than about 200 μm may be given to a thickness of the molding layer 300 on the second lateral surfaces 21S2 of the first upper semiconductor chips 210B. For example, a range of about 0.00001 μm to about 200 μm may be given to the thickness of the molding layer 300 on the second lateral surfaces 21S2 of the first upper semiconductor chip 210B.

FIG. 2D illustrates an enlarged cross-sectional view of section Z depicted in FIG. 1B, showing a molding layer according to some embodiments.

Referring to FIG. 2D, a recess may be provided on the top surface at the edge region R2 of the interposer substrate 100. A top surface 100a2 at the edge region R2 of the interposer substrate 100 may be located at a lower level than that of a top surface 100a1 at the central region R1 of the interposer substrate 100. The interposer substrate 100 may further have a first lateral surface 100c. The first lateral surface 100c of the interposer substrate 100 may be provided between the central region R1 and the edge region R2 of the interposer substrate 100. For example, the first lateral surface 100c of the interposer substrate 100 may be provided between the top surface 100a2 at the edge region R2 of the interposer substrate 100 and the top surface 100a1 at the central region R1 of the interposer substrate 100. The first lateral surface 100c of the interposer substrate 100 may be vertically aligned with the outer sidewall of the under-fill layer 400, the second sidewall 20S2 of the first lower semiconductor chip 210A, and the outer sidewall 310c of the molding pattern 310.

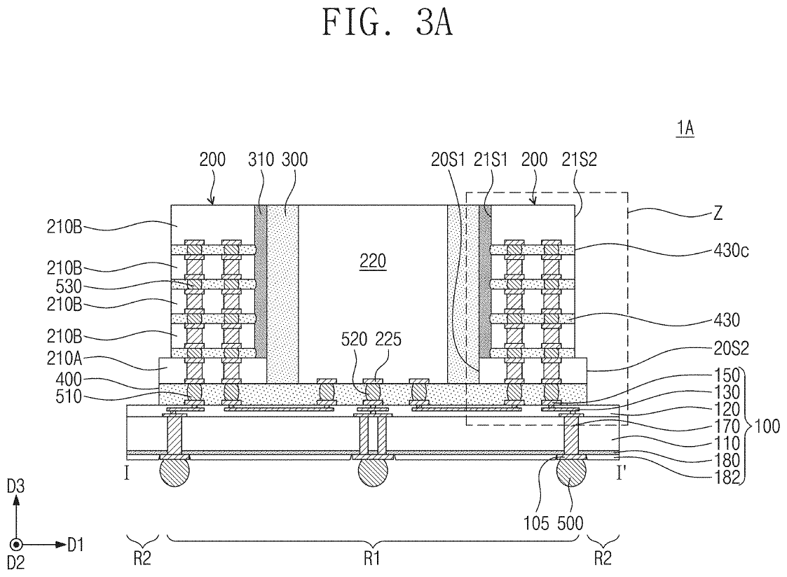

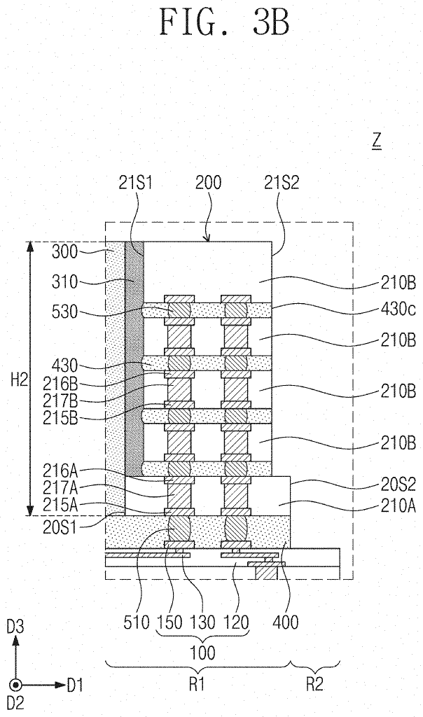

FIG. 3A illustrates a cross-sectional view taken along line I-I′ of FIG. 1A, showing a semiconductor package according to some embodiments. FIG. 3B illustrates an enlarged cross-sectional view showing section Z of FIG. 3A.

Referring to FIGS. 3A and 3B, a semiconductor package may include a first package 1A. The first package 1A may include connection solders 500, an interposer substrate 100, a chip stack 200, a second semiconductor chip 220, and a molding layer 300. The first package 1A may further include first bumps 510, second bumps 520, and an under-fill layer 400.

The chip stack 200 may include a first lower semiconductor chip 210A, first upper semiconductor chips 210B, a molding pattern 310, under-fill patterns 430, and conductive bumps 530. The chip stack 200 may be substantially the same as that discussed in the embodiments of FIGS. 1A to 1D. In contrast, the second lateral surfaces 21S2 of the first upper semiconductor chips 210B may not be covered with but may be exposed by the molding pattern 310. For example, the second lateral surfaces 21S2 of the first upper semiconductor chips 210B may be exposed to air of an external space. The molding pattern 310 may further expose at least a portion of the top surface of the first lower semiconductor chip 210A. Therefore, the occurrence of a crack may be effectively prevented or reduced.

The second lateral surfaces 21S2 of the first upper semiconductor chips 210B may be vertically aligned with outer sidewalls 430c of the under-fill patterns 430.

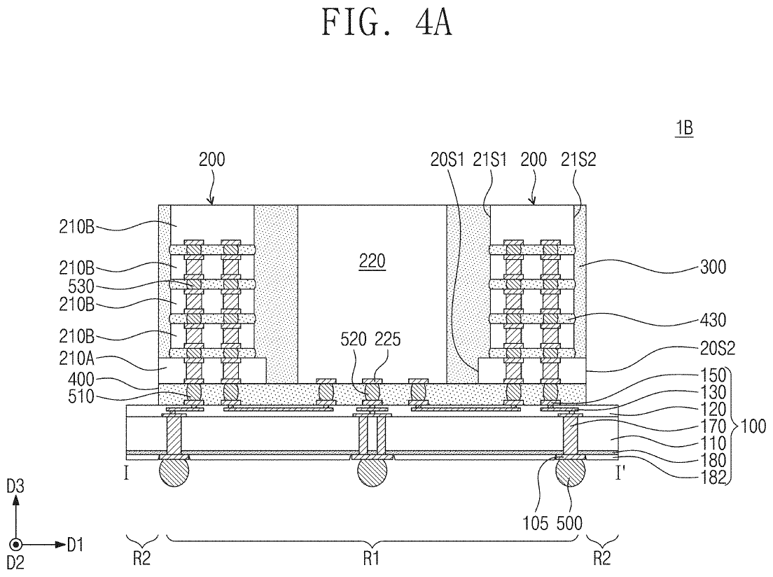

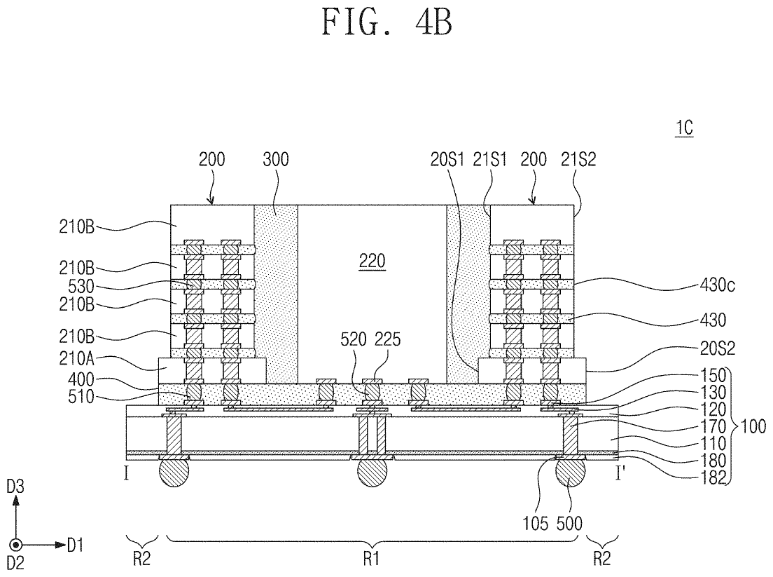

FIG. 4A illustrates a cross-sectional view taken along line I-I′ of FIG. 1A, showing a semiconductor package according to some embodiments.

Referring to FIG. 4A, a semiconductor package may include a first package 1B. The first package 1B may include connection solders 500, an interposer substrate 100, a chip stack 200, a second semiconductor chip 220, an under-fill layer 400, and a molding layer 300. The chip stack 200 may be substantially the same as that discussed in the embodiments of FIGS. 1A to 1E. In contrast, the chip stack 200 may not include the molding pattern 310 discussed in FIGS. 1B to 1D.

The molding layer 300 may expose the first sidewall 20S1 of the first lower semiconductor chip 210A. The molding layer 300 may extend onto the top surface of the first lower semiconductor chip 210A to cover the first lateral surfaces 21S1 and the second lateral surfaces 21S2 of the first upper semiconductor chips 210B. For example, the molding layer 300 may be in contact with the first lateral surfaces 21S1 and the second lateral surfaces 21S2 of the first upper semiconductor chips 210B. The molding layer 300 may further cover the outer sidewalls 430c of the under-fill patterns 430. The molding layer 300 may have an outer sidewall that is vertically aligned with the second sidewall 20S2 of the first lower semiconductor chip 210A and with the outer sidewall of the under-fill layer 400.

Although not shown, the molding layer 300 may further cover the third lateral surfaces 21S3 and the fourth lateral surfaces 21S4 of the first upper semiconductor chips 210B discussed in the embodiment of FIG. 1D.

FIG. 4B illustrates a cross-sectional view taken along line I-I′ of FIG. 1A, showing a semiconductor package according to some embodiments.

Referring to FIG. 4B, a semiconductor package may include a first package 1C. The first package 1C may include connection solders 500, an interposer substrate 100, a chip stack 200, a second semiconductor chip 220, an under-fill layer 400, and a molding layer 300. The chip stack 200 may be substantially the same as that discussed in the embodiments of FIGS. 1A to 1E. In contrast, the chip stack 200 may not include the molding pattern 310 discussed in FIGS. 1B to 1D.

The molding layer 300 may expose the first sidewall 20S1 of the first lower semiconductor chip 210A. The molding layer 300 may extend onto the top surface of the first lower semiconductor chip 210A to cover the first lateral surfaces 21S1 of the first upper semiconductor chips 210B. The molding layer 300 may not cover the second sidewall 20S2 of the first lower semiconductor chip 210A or the second lateral surfaces 21S2 of the first upper semiconductor chips 210B. The second sidewall 20S2 of the first lower semiconductor chip 210A and the second lateral surfaces 21S2 of the first upper semiconductor chips 210B may be exposed to an external space. The second lateral surfaces 21S2 of the first upper semiconductor chips 210B may be vertically aligned with the outer sidewalls 430c of the under-fill patterns 430.

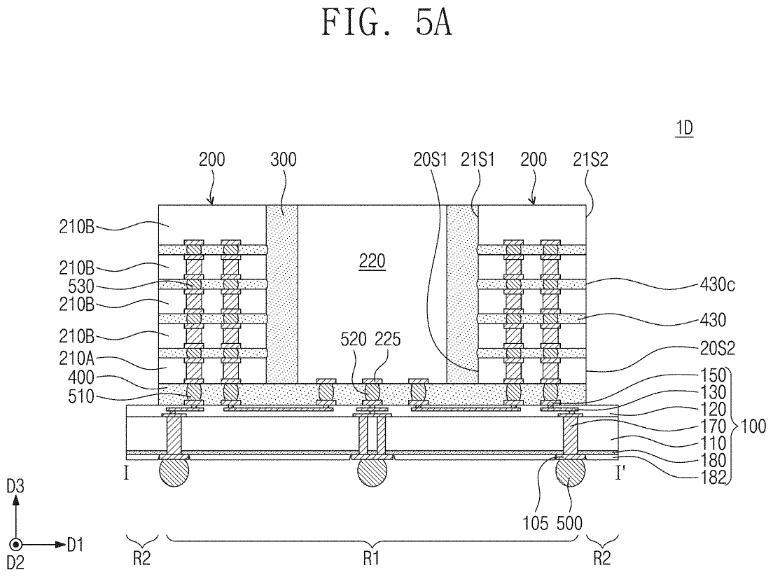

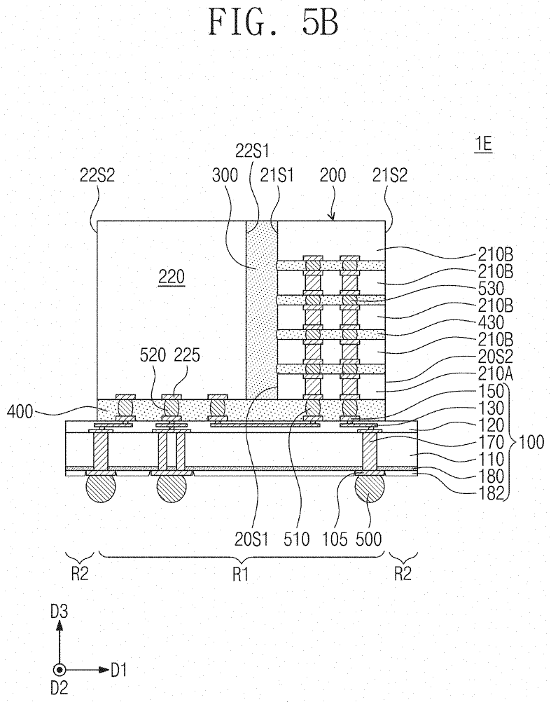

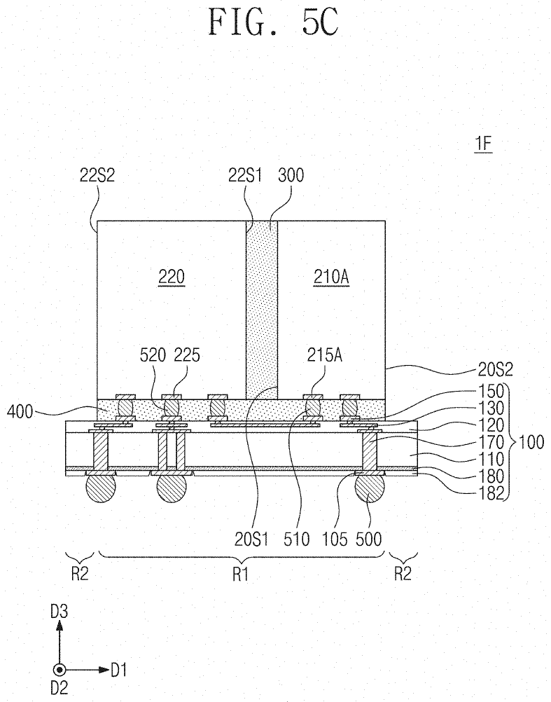

FIG. 5A illustrates a cross-sectional view taken along line I-I′ of FIG. 1A, showing a semiconductor package according to some embodiments.

Referring to FIG. 5A, a semiconductor package may include a first package 1D. The first package 1D may include connection solders 500, an interposer substrate 100, a chip stack 200, a second semiconductor chip 220, an under-fill layer 400, and a molding layer 300.

The chip stack 200 may include a first lower semiconductor chip 210A and first upper semiconductor chips 210B. The first upper semiconductor chips 210B may have their widths substantially the same as that of the first lower semiconductor chip 210A. The chip stack 200 may not include the molding pattern 310 discussed in FIGS. 1B to 1D.

The molding layer 300 may cover the first sidewall 20S1 of the first lower semiconductor chip 210A and the first lateral surfaces 21S1 of the first upper semiconductor chips 210B. The molding layer 300 may expose the second sidewall 20S2 of the first lower semiconductor chip 210A and the second lateral surfaces 21S2 of the first upper semiconductor chips 210B. The second sidewall 20S2 of the first lower semiconductor chip 210A may be vertically aligned with the second lateral surfaces 21S2 of the first upper semiconductor chips 210B and with the outer sidewalls 430c of the under-fill patterns 430.

FIG. 5B illustrates a cross-sectional view showing a semiconductor package according to some embodiments.

Referring to FIG. 5B, a semiconductor package may include a first package 1E. The first package 1E may include connection solders 500, an interposer substrate 100, a single chip stack 200, a second semiconductor chip 220, an under-fill layer 400, and a molding layer 300. The second semiconductor chip 220 may have a first sidewall 22S1 and a second sidewall 22S2 that are opposite to each other. The first sidewall 22S1 of the second semiconductor chip 220 may face the chip stack 200.

The molding layer 300 may be interposed between the second semiconductor chip 220 and the chip stack 200 to cover the first sidewall 22S1 of the second semiconductor chip 220, the first sidewall 20S1 of the first lower semiconductor chip 210A, and the first lateral surfaces 21S1 of the first upper semiconductor chips 210B. The second sidewall 20S2 of the first lower semiconductor chip 210A and the second sidewall 22S2 of the second semiconductor chip 220 may not be covered with but may be exposed by the molding layer 300. The exposed second sidewall 22S2 of the second semiconductor chip 220 may be vertically aligned with the outer sidewall of the under-fill layer 400. The molding layer 300 may further expose the second lateral surfaces 21S2 of the first upper semiconductor chips 210B.

FIG. 5C illustrates a cross-sectional view showing a semiconductor package according to some embodiments.

Referring to FIG. 5C, a semiconductor package may include a first package 1F. The first package 1F may include connection solders 500, an interposer substrate 100, a first lower semiconductor chip 210A, a second semiconductor chip 220, an under-fill layer 400, and a molding layer 300. The first package 1F may not include the first upper semiconductor chips 210B, the under-fill patterns 430, or the conductive bumps 530 discussed in the embodiments of FIGS. 1A to 1E. The first lower semiconductor chip 210A may include the first lower pads 215A, but may not include the first conductive vias 217A or the first upper pads 216A discussed in the embodiments of FIGS. 1B to 1E. The first lower pads 215A may be chip pads.

The molding layer 300 may be interposed between the first sidewall 20S1 of the first lower semiconductor chip 210A and the first sidewall 22S1 of the second semiconductor chip 220, and may expose the second sidewall 20S2 of the first lower semiconductor chip 210A and the second sidewall 22S2 of the second semiconductor chip 220. The molding layer 300 may have a top surface located at substantially the same as that of the top surface of the first lower semiconductor chip 210A and that of the top surface of the second semiconductor chip 220.

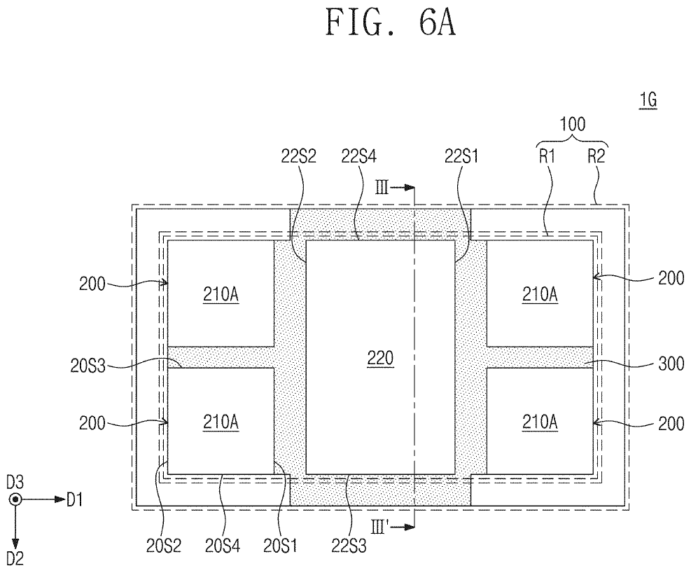

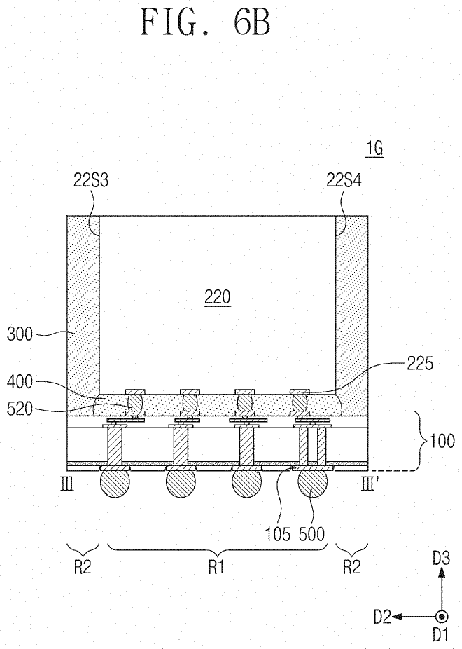

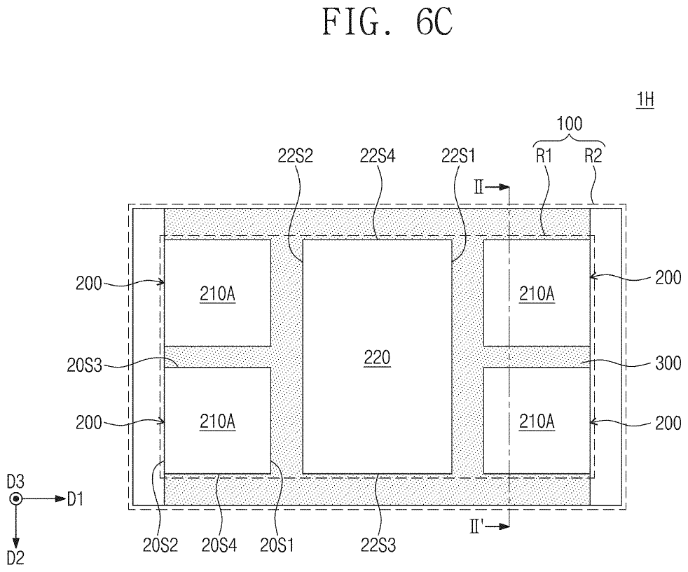

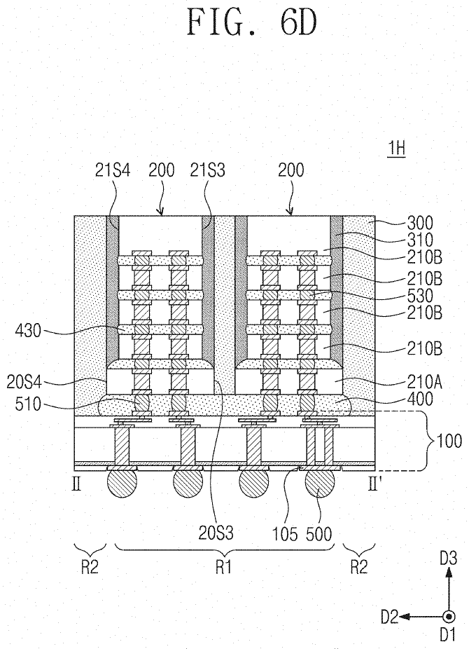

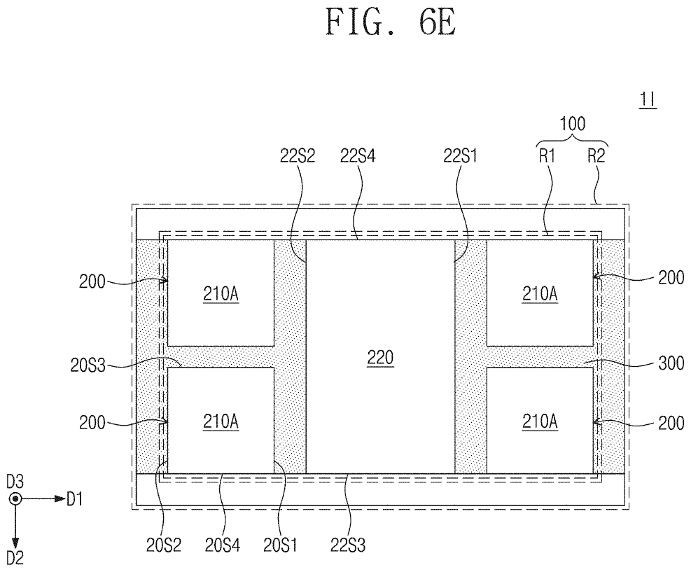

FIG. 6A illustrates a plan view showing a semiconductor package according to some embodiments. FIG. 6B illustrates a cross-sectional view taken along line of FIG. 6A. FIGS. 1B and 1D will also be referred to in explaining FIGS. 6A and 6B.

Referring to FIGS. 6A and 6B, a semiconductor package may include a first package 1G. The first package 1G may include connection solders 500, an interposer substrate 100, a first lower semiconductor chip 210A, a second semiconductor chip 220, an under-fill layer 400, and a molding layer 300.

The molding layer 300 may be interposed between the chip stacks 200 and the second semiconductor chip 220 and between the chip stacks 200, thereby covering the first sidewall 20S1 and the third sidewall 20S3 of the first lower semiconductor chip 210A. The molding layer 300 may expose the second sidewall 20S2 and the fourth sidewall 20S4 of the first lower semiconductor chip 210A. The molding layer 300 may cover the first sidewall 22S1, the second sidewall 22S2, the third sidewall 22S3, and the fourth sidewall 22S4 of the second semiconductor chip 220. The molding layer 300 may protect the second semiconductor chip 220.

FIG. 6C illustrates a plan view showing a semiconductor package according to some embodiments. FIG. 6D illustrates a cross-sectional view taken along line II-II′ of FIG. 6C. FIGS. 1B and 6B will also be referred to in explaining FIGS. 6C and 6D.

Referring to FIGS. 6C and 6D, a semiconductor package may include a first package 1H. The first package 1H may include connection solders 500, an interposer substrate 100, a first lower semiconductor chip 210A, a second semiconductor chip 220, an under-fill layer 400, and a molding layer 300.

The molding layer 300 may be provided on the top surface at the central region R1 of the interposer substrate 100, and may be disposed between the chip stacks 200 and the second semiconductor chip 220 and between the chip stacks 200. The molding layer 300 may further be provided on a portion of the edge region R2 of the interposer substrate 100. For example, on the top surface at the edge region R2 of the interposer substrate 100, the molding layer 300 may further be provided on the fourth sidewall 20S4 of the first lower semiconductor chip 210A. The fourth sidewall 20S4 of the first lower semiconductor chip 210A may not be vertically aligned with a corresponding outer sidewall of the under-fill layer 400. The molding layer 300 may further cover the outer sidewall of the under-fill layer 400. The outer sidewall of the under-fill layer 400 may be directed toward in the second direction D2 or in a direction reverse to the second direction D2. The molding layer 300 may not cover the second sidewall 20S2 of the first lower semiconductor chip 210A. As discussed above in FIG. 6B, the molding layer 300 may further cover the third sidewall 20S3 and the fourth sidewall 20S4 of the second semiconductor chip 220.

FIG. 6E illustrates a plan view showing a semiconductor package according to some embodiments. FIGS. 1D and 1E will also be referred to in explaining FIGS. 6C and 6D.

Referring to FIG. 6E, a semiconductor package may include a first package H. The first package 1I may include an interposer substrate 100, a first lower semiconductor chip 210A, a second semiconductor chip 220, and a molding layer 300.

The molding layer 300 may expose the first sidewall 20S1, the second sidewall 20S2, and the third sidewall 20S3 of the first lower semiconductor chip 210A, but may expose the fourth sidewall 20S4 of the first lower semiconductor chip 210A. The molding layer 300 may cover the first sidewall 22S1 and the second sidewall 22S2 of the second semiconductor chip 220, but may expose the third sidewall 22S3 and the fourth sidewall 22S4 of the second semiconductor chip 220.

Some embodiments of the present inventive concepts may be combined with each other. For example, the molding layer 300 discussed in the embodiment of FIG. 2A, 2B, or 2D may be included in one of the first package 1A of FIGS. 3A and 3B, the first package 1B of FIG. 4A, the first package 1C of FIG. 4B, the first package 1D of FIG. 5A, the first package 1E of FIG. 5B, the first package 1F of FIG. 5C, the first package 1G of FIGS. 6A and 6B, the first package 1H of FIGS. 6C and 6D, and the first package 1I of FIG. 6E. For example, the molding layer 300 may further be provided on the edge region R2 of the interposer substrate 100, and the top surface of the molding layer 300 on the edge region R2 of the interposer substrate 100 may be located at a lower level than that of the top surfaces of the first bumps 510. For another example, the molding layer 300 may cover the first sidewall 20S1 of the first lower semiconductor chip 210A, and the molding layer 300 on the first sidewall 20S1 of the first lower semiconductor chip 210A may have a thickness of equal to or less than about 200 μm.

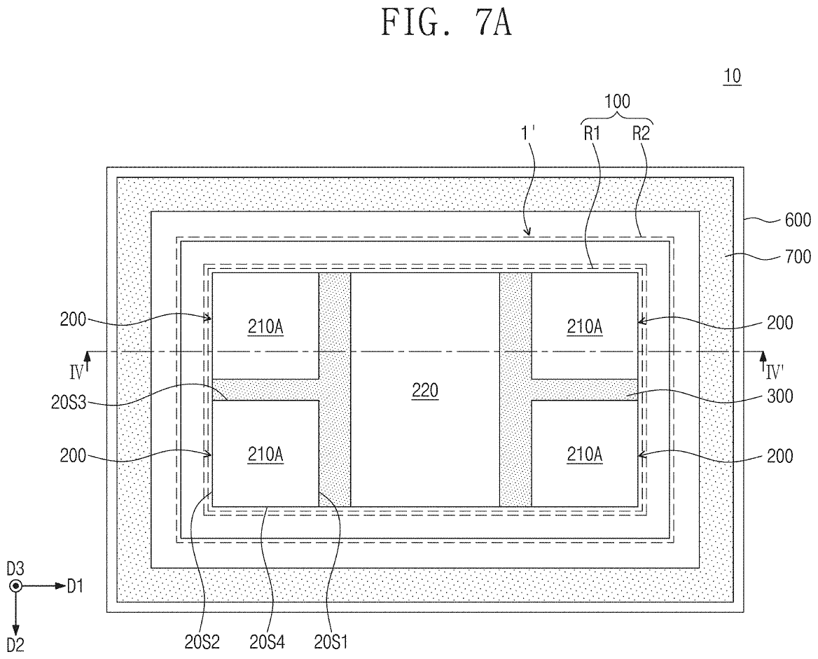

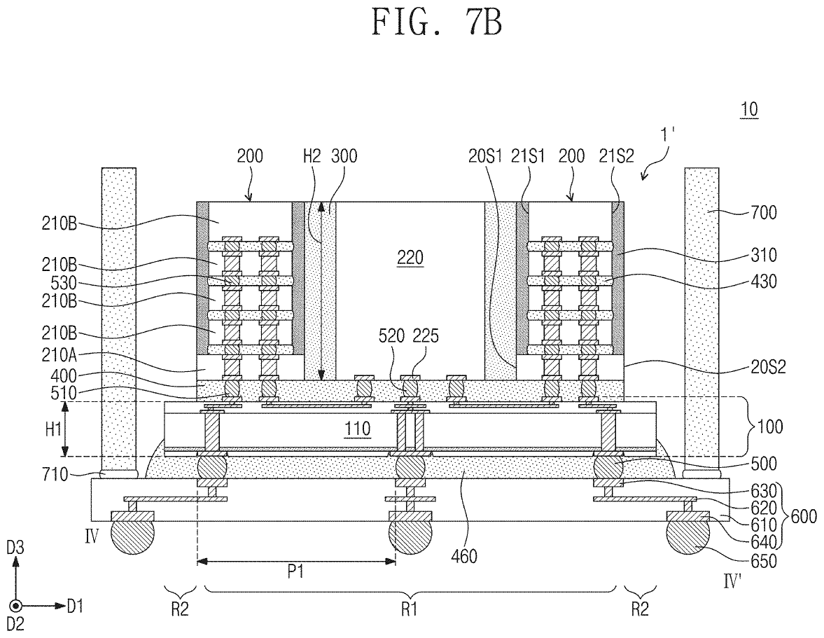

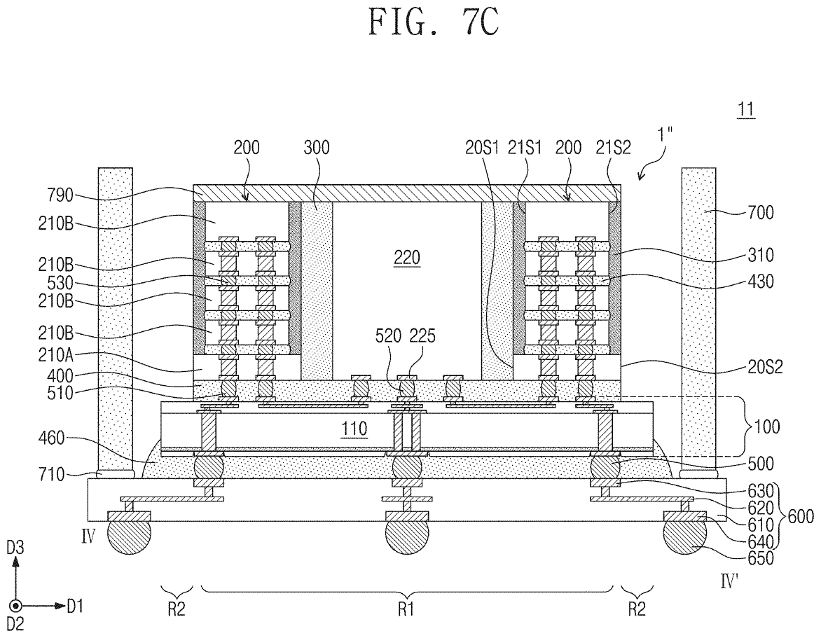

FIG. 7A illustrates a plan view showing a semiconductor package according to some embodiments. FIG. 7B illustrates a cross-sectional view taken along line IV-IV′ of FIG. 7A.

Referring to FIGS. 7A and 7B, a semiconductor package 10 may include a first package 1′, solder terminals 650, a package substrate 600, a lower under-fill layer 460, a stiffener 700, and an adhesion layer 710. The first package 1′ may be substantially the same as the first package 1 discussed in FIGS. 1A to 1E. For another example, the first package 1′ may be one of the first package 1A of FIGS. 3A and 3B, the first package 1B of FIG. 4A, the first package 1C of FIG. 4B, the first package 1D of FIG. 5A, the first package 1E of FIG. 5B, the first package 1F of FIG. 5C, the first package 1G of FIGS. 6A and 6B, the first package 1H of FIGS. 6C and 6D, and the first package 1I of FIG. 6E. The first package 1′ may include connection solders 500, an interposer substrate 100, a chip stack 200, a second semiconductor chip 220, an under-fill layer 400, and a molding layer 300. The first package 1′ may include first bumps 510, second bumps 520, and an under-fill layer 400.

The package substrate 600 may include, for example, a printed circuit board (PCB). The package substrate 600 may have a central region and an edge region when viewed in plan. When viewed in plan, the edge region of the package substrate 600 may be provided between a lateral surface of the package substrate 600 and the central region of the package substrate 600.

The package substrate 600 may include a dielectric base layer 610, conductive patterns 620, substrate pads 630, and terminal pads 640. The dielectric base layer 610 may include a multiple layer. Alternatively, the dielectric base layer 610 may be a single layer. The substrate pads 630 and the terminal pads 640 may be respectively provided on a top surface and a bottom surface of the package substrate 600. The conductive patterns 620 may be disposed in the dielectric base layer 610. The terminal pads 640 may be coupled through the conductive patterns 620 to the substrate pads 630. The phrase “electrically connected to the package substrate 600” may mean that “electrically connected to at least one of the conductive patterns 620.” The substrate pads 630, the conductive patterns 620, and the terminal pads 640 may include metal, such as one or more of copper, aluminum, tungsten, and titanium.

The solder terminals 650 may be provided on the bottom surface of the package substrate 600 and may be electrically connected to the conductive patterns 620. External electrical signals may be transferred to the solder terminals 650. The solder terminals 650 may include solder balls.

The first package 1′ may be disposed on the package substrate 600. For example, the interposer substrate 100 may be provided on the top surface at the central region of the package substrate 600. The connection solders 500 may be correspondingly coupled to the substrate pads 630. Therefore, the chip stacks 200 and the second semiconductor chip 220 may be electrically connected through the interposer substrate 100 to the package substrate 600.

The lower under-fill layer 460 may be provided in a gap between the package substrate 600 and the interposer substrate 100, thereby covering sidewalls of the connection solders 500. The lower under-fill layer 460 may protect the connection solders 500. The lower under-fill layer 460 may further cover outer sidewalls of the interposer substrate 100. The lower under-fill layer 460 may include a dielectric polymer, such as an epoxy-based polymer.

The package substrate 600 may have a coefficient of thermal expansion greater than that of the lower under-fill layer 460 and that of the interposer substrate 100. For example, the package substrate 600 may have a coefficient of thermal expansion greater than that of the lower under-fill layer 460 and that of the semiconductor die 110. The semiconductor package 10 may experience warpage caused by a difference in a coefficient of thermal expansion between the package substrate 600 and the semiconductor die 110 or between the lower under-fill layer 460 and the semiconductor die 110. According to some embodiments, the molding layer 300 may have a coefficient of thermal expansion greater than that of the semiconductor die 110. Therefore, a difference in a coefficient of thermal expansion between the molding layer 300 and the semiconductor die 110 may counterbalance the difference in a coefficient of thermal expansion between the package substrate 600 and the semiconductor die 110 or between the lower under-fill layer 460 and the semiconductor die 110. The molding layer 300 may satisfy a condition that its first height H2 is about 5 times to about 10 times the height H1 of the interposer substrate 100, and thus the difference in a coefficient of thermal expansion between the molding layer 300 and the semiconductor die 110 may effectively counterbalance the difference in a coefficient of thermal expansion between the package substrate 600 and the semiconductor die 110 or between the lower under-fill layer 460 and the semiconductor die 110. Accordingly, the semiconductor package 10 may be prevented or reduced from warpage.

The stiffener 700 may be disposed on the edge region of the package substrate 600. The stiffener 700 may be placed laterally spaced apart from the molding layer 300 and the chip stack 200. The stiffener 700 may include, for example, one or more of copper, stainless steels (SUS), aluminum silicon carbide (AlSiC), and titanium. For example, warpage may occur at the edge region of the package substrate 600. The stiffener 700 may have relatively large stiffness to fix the edge region of the package substrate 600. Therefore, the package substrate 600 may be prevented or reduced from warpage.

The stiffener 700 may be laterally spaced apart from the second sidewall 20S2 of the first lower semiconductor chip 210A. The stiffener 700 may have an inner sidewall that faces the second sidewall 20S2 of the first lower semiconductor chip 210A. Even when the second sidewall 20S2 of the first lower semiconductor chip 210A is exposed to an external space, the stiffener 700 may prevent or reduce the first lower semiconductor chip 210A from being damaged.

The adhesion layer 710 may be interposed between the package substrate 600 and the stiffener 700. The adhesion layer 710 may fix the stiffener 700 to the package substrate 600. The adhesion layer 710 may have dielectric properties or conductive properties. The adhesion layer 710 may include an organic material or metal.

FIG. 7C illustrates a cross-sectional view taken along line IV-IV′ of FIG. 7A, showing a semiconductor package according to some embodiments.

Referring to FIG. 7C, a semiconductor package 11 may include a first package 1″, solder terminals 650, a package substrate 600, a lower under-fill layer 460, a stiffener 700, and an adhesion layer 710. The first package 1″ may be substantially the same as that discussed above with reference to FIGS. 7A and 7B. The first package 1″ may further include a thermal radiator 790.

The thermal radiator 790 may be provided on a top surface of the second semiconductor chip 220, top surfaces of the chip stacks 200, and a top surface of the molding layer 300. For example, the thermal radiator 790 may cover a top surface of the uppermost first upper semiconductor chip 210B. Although not shown, the thermal radiator 790 may extend onto outer sidewalls of the molding layer 300. The thermal radiator 790 may include a heat sink, a heat slug, or a thermal interface material (TIM) layer. The thermal radiator 790 may have a thermal conductivity greater than that of the molding layer 300. When the semiconductor package 11 operates, the thermal radiator 790 may promptly outwardly discharge heat generated from the chip stacks 200 and/or the second semiconductor chip 220. The thermal radiator 790 may include metal, such as copper. The thermal radiator 790 may absorb external physical impacts to thereby protect the second semiconductor chip 220 and the chip stacks 200.

The thermal radiator 790 may have an electrical conductivity to thereby serve as an electromagnetic field shield layer. In this case, the thermal radiator 790 may shield electromagnetic interference (EMI) of the chip stacks 200 and the second semiconductor chip 220. In this case, a ground voltage may be applied to the thermal radiator 790.

FIGS. 8A to 8M illustrate cross-sectional views showing a method of fabricating a semiconductor package according to some embodiments. A duplicate description will be omitted below. In explaining FIGS. 8A to 8M, for convenience of description, top and bottom surfaces of a certain component will be discussed based on a related figure.

Referring to FIG. 8A, a semiconductor wafer 110W may be prepared. The semiconductor wafer 110W may include a plurality of semiconductor dies 110. The semiconductor dies 110 may be connected to each other. The semiconductor dies 110 may be defined by a scribe lane (not shown) provided on one surface of the semiconductor wafer 110W, but the present inventive concepts are not limited thereto.

The formation of the semiconductor wafer 110W may include forming through vias 170, forming a dielectric layer 120, forming wiring structures 130, and forming interposer pads 150.

The through vias 170 may be formed in the semiconductor wafer 110W. The through vias 170 may penetrate top surfaces of the semiconductor dies 110, but may not penetrate bottom surfaces of the semiconductor dies 110. The through vias 170 may have their bottom surfaces provided in the semiconductor dies 110.

The dielectric layer 120 may be formed on a top surface of the semiconductor wafer 110W. The wiring structures 130 may be formed in the dielectric layer 120 to be coupled to the through vias 170. The interposer pads 150 may be formed on and coupled to corresponding wiring structures 130.

Referring to FIG. 8B, the semiconductor wafer 110W may be turned upside down to allow the interposer pads 150 to face downward.

A first carrier substrate 910 may be provided on the dielectric layer 120. A first release layer 913 may be interposed between the first carrier substrate 910 and the dielectric layer 120. The first carrier substrate 910 may be attached through the first release layer 913 to the dielectric layer 120. Before the semiconductor wafer 110W is turned upside down, the first carrier substrate 910 may be attached.

Referring to FIG. 8C, a thinning process may be performed on the semiconductor wafer 110W. The thinning process may include a grinding process or an etch-back process. The thinning process may remove upper portions of the semiconductor dies 110. The thinning process may cause the through vias 170 to have their protrusions 170Z. The protrusions 170Z of the through vias 170 may be located at a higher level than that of the top surfaces of the thinned semiconductor dies 110.

Referring to FIG. 8D, a first passivation layer 180P may be formed on the semiconductor wafer 110W. The first passivation layer 180P may cover the top surfaces of the semiconductor dies 110 and the protrusions 170Z of the through vias 170. A deposition process may be performed to form the first passivation layer 180P. The deposition process may be a wafer-level deposition process.

Referring to FIG. 8E, a polishing process may be performed on the first passivation layer 180P. As illustrated by dotted lines, the polishing process may remove a portion of the first passivation layer 180P and the protrusions 170Z of the through vias 170. The portion of the first passivation layer 180P may be segments that cover the protrusions 170Z of the through vias 170. As a result of the polishing process, surfaces of the through vias 170 may be exposed. The surfaces of the through vias 170 may be located at substantially the same level as that of a top surface of the first passivation layer 180P. The polishing process may include a chemical mechanical polishing process.

Referring to FIG. 8F, a second passivation layer 182P may be formed on the first passivation layer 180P, covering the first passivation layer 180P. A coating process may be performed to form the second passivation layer 182P, but the present inventive concepts are not limited thereto. Openings may be formed in the second passivation layer 182P to expose the surfaces of the through vias 170. Therefore, a preliminary interposer substrate 100P may be eventually manufactured. The preliminary interposer substrate 100P may include the semiconductor wafer 110W, the through vias 170, the dielectric layer 120, the wiring structures 130, the interposer pads 150, the first passivation layer 180P, and the second passivation layer 182P.

Solder pads 105 may be correspondingly formed on the exposed surfaces of the through vias 170, thereby being coupled to the through vias 170. Connection solders 500 may be correspondingly formed on the solder pads 105.

Referring to FIG. 8G, the preliminary interposer substrate 100P may be turned upside down to allow the connection solders 500 to face downward. A second carrier substrate 920 may be provided on a bottom surface of the preliminary interposer substrate 100P. A second release layer 923 may be provided between the second carrier substrate 920 and the preliminary interposer substrate 100P, covering the connection solders 500. The second carrier substrate 920 may be attached through the second release layer 923 to the preliminary interposer substrate 100P. Afterwards, the first carrier substrate 910 and the first release layer 913 may be removed to expose the interposer pads 150.

Referring to FIG. 8H, chip stacks 200 and a second semiconductor chip 220 may be mounted on the preliminary interposer substrate 100P. As discussed above, each of the chip stacks 200 may include a first lower semiconductor chip 210A, one or more first upper semiconductor chips 210B, conductive bumps 530, under-fill patterns 430, and a molding pattern 310. The mounting of the chip stacks 200 may include placing the chip stacks 200 on the interposer substrate 100 and forming first bumps 510. The first bumps 510 may be formed between the first lower semiconductor chip 210A and the preliminary interposer substrate 100P. The mounting of the second semiconductor chip 220 may include forming second bumps 520 between the second semiconductor chip 220 and the preliminary interposer substrate 100P.

An under-fill layer 400 may be formed in a first gap between the preliminary interposer substrate 100P and the first lower semiconductor chip 210A and in second gaps between the preliminary interposer substrate 100P and the chip stacks 200. The under-fill layer 400 may encapsulate the first bumps 510 and the second bumps 520. The under-fill layer 400 may have a distal end that protrudes on an edge region R2 of the preliminary interposer substrate 100P. For example, at least a portion of the under-fill layer 400 may vertically overlap a second sidewall 20S2 of the first lower semiconductor chip 210A.

Referring to FIG. 8I, a preliminary molding layer 300P may be formed on central and edge regions R1 and R2 of the preliminary interposer substrate 100P. The preliminary molding layer 300P may cover the second semiconductor chip 220, the chip stacks 200, and the under-fill layer 400. The preliminary molding layer 300P may further cover a top surface of the second semiconductor chip 220 and top surfaces of the chip stacks 200. The preliminary molding layer 300P may be formed in a wafer-level process.

Referring to FIG. 8J, the preliminary molding layer 300P may undergo a grinding process to remove a portion of the preliminary molding layer 300P. The grinding process may continue until the top surface of the second semiconductor chip 220 are exposed and the top surfaces of the chip stacks 200 are exposed. Therefore, a top surface of the preliminary molding layer 300P may be located at substantially the same level as that of a top surface of an uppermost first upper semiconductor chip 210B, the top surface of the second semiconductor chip 220, and a top surface of the molding pattern 310.

Referring sequentially to FIGS. 8J and 8K, the second carrier substrate 920 and the second release layer 923 may be removed to expose the connection solders 500 and a bottom surface of the preliminary interposer substrate 100P.

A dicing tape 930 may be attached to the top surfaces of the chip stacks 200, a top surface of the first lower semiconductor chip 210A, and the top surface of the preliminary molding layer 300P.

A sawing process may be performed on the second passivation layer 182P, the first passivation layer 180P, the preliminary interposer substrate 100P, and the preliminary molding layer 300P, thereby forming grooves 390. A blade may be used to perform the sawing process. The grooves 390 may penetrate the second passivation layer 182P, the first passivation layer 180P, the preliminary interposer substrate 100P, and the preliminary molding layer 300P, thereby exposing the dicing tape 930. The second passivation layer 182P, the first passivation layer 180P, and the preliminary molding layer 300P may be diced to respectively form second passivation patterns 182, first passivation patterns 180, and molding layers 300. The grooves 390 may separate the molding layers 300 from each other. The grooves 390 may separate the first passivation patterns 180 from each other. The grooves 390 may separate the second passivation patterns 182 from each other. The semiconductor wafer 110W may be diced into a plurality of semiconductor dies 110 that are separated from each other. In the sawing process, the preliminary interposer substrate 100P may be formed into a plurality of interposer substrates 100 that are separated from each other. Each of the interposer substrates 100 may include the semiconductor die 110, the through vias 170, the dielectric layer 120, the wiring structures 130, the interposer pads 150, the first passivation pattern 180, and the second passivation pattern 182.

As a result of the sawing process, preliminary packages IP may be manufactured. Each of the preliminary packages IP may include the interposer substrate 100, the connection solders 500, the chip stacks 200, the second semiconductor chip 220, the first bumps 510, the second bumps 520, the under-fill layer 400, and the molding layer 300. Thereafter, the dicing tape 930 may be removed to expose a top surface of the molding layer 300, the top surfaces of the chip stacks 200, and the top surface of the second semiconductor chip 220. For brevity of description, the following will illustrate and discuss a single preliminary package IP.

Referring to FIG. 8L, the preliminary package IP may be mounted on the central region R1 of the package substrate 600. The mounting of the preliminary package IP may include coupling the connection solders 500 to corresponding substrate pads 630.

According to some embodiments, a first height H2 of the molding layer 300 may be about 5 times to about 10 times a height H1 of the interposer substrate 100. Therefore, the molding layer 300 may fix the interposer substrate 100 to prevent or reduce warpage of the interposer substrate 100. The molding layer 300 may be provided on the central region R1 and the edge region R2 of the interposer substrate 100, and thus the interposer substrate 100 may be effectively prevented or reduced from warpage.

Afterwards, a lower under-fill layer 460 may be formed between the package substrate 600 and the interposer substrate 100, thereby encapsulating the connection solders 500.

Referring to FIG. 8M, a portion of the molding layer 300 may be removed to expose the second sidewall 20S2 of the first lower semiconductor chip 210A. Before the molding layer 300 is removed, a mask pattern 990 may further be formed on the top surface of the second semiconductor chip 220, a portion of the top surface of the molding layer 300, and the top surfaces of the chip stacks 200. The molding layer 300 may have a portion exposed by the mask pattern 990, and the exposed portion of the molding layer 300 may be removed. For example, the molding layer 300 may have a portion on the edge region R2 of the interposer substrate 100, and the portion of the molding layer 300 may be removed. When the molding layer 300 is partially removed, a distal end of the under-fill layer 400 may be removed together with the molding layer 300. Therefore, the second sidewall 20S2 of the first lower semiconductor chip 210A may be vertically aligned with an outer sidewall of the under-fill layer 400. The partial removal of the molding layer 300 may be achieved by performing a laser drilling process. After the partial removal of the molding layer 300, the mask pattern 990 may be removed. A first package 1 may be eventually fabricated through the aforementioned exemplary fabrication. The first package 1 may be substantially the same as that discussed in the embodiments of FIGS. 1A to 1E. An arrangement of the mask pattern 990 may be variously changed. Alternatively, the mask pattern 990 may not be formed, and thus the molding layer 300 may be partially removed without using the mask pattern 990.

For another example, after the partial removal of the molding layer 300, at least a portion of the molding layer 300 may remain on a top surface at the edge region R2 of the interposer substrate 100. In this case, as shown in FIG. 2A, the molding layer 300 may include a first part 301 and a second part 302. The under-fill layer 400 may be partially removed from the top surface at the edge region R2 of the interposer substrate 100.

For another example, as shown in FIG. 2B, at least a portion of the molding layer 300 may remain on the second sidewall 20S2 of the first lower semiconductor chip 210A and the outer sidewall 310c of the molding pattern 310.

For another example, as shown in FIG. 2C, at least a portion of the molding layer 300 may remain on the top surface at the edge region R2 of the interposer substrate 100. The molding layer 300 may include a first part 301 and a second part 302. The second part 302 of the molding layer 300 may further remain on the second sidewall 20S2 of the first lower semiconductor chip 210A and the outer sidewall 310c of the molding pattern 310.

For another example, as shown in FIG. 2D, after the molding layer 300 is removed from the edge region R2 of the interposer substrate 100, an upper portion of the interposer substrate 100 may be removed from the edge region R2. Therefore, a top surface 100a2 at the edge region R2 of the interposer substrate 100 may be located at a lower level than that of a top surface 100a1 at the central region R1 of the interposer substrate 100.

For another example, as shown in FIGS. 3A and 3B, a portion of the molding layer 300 and a portion of the molding pattern 310 may further be removed to expose the second sidewall 20S2 of the first lower semiconductor chip 210A and second lateral surfaces 21S2 of the first upper semiconductor chip 210B. In this step, distal ends of the under-fill patterns 430 may also be removed. The distal ends of the under-fill patterns 430 may be portions that protrude outwardly from the second lateral surfaces 21S2 of the first upper semiconductor chips 210B. Therefore, the second lateral surfaces 21S2 of the first upper semiconductor chip 210B may be vertically aligned with the outer sidewalls 430c of the under-fill patterns 430.

Referring back to FIG. 7B, after the partial removal of the molding layer 300, a stiffener 700 may be disposed on a top surface at the edge region R2 of the package substrate 600. An adhesion layer 710 may be formed between the package substrate 600 and the stiffener 700. A paste may be used to form the adhesion layer 710.

Solder terminals 650 may be formed on a bottom surface of the package substrate 600. For example, the solder terminals 650 may be formed on bottom surfaces of the terminal pads 640. Through the aforementioned exemplary fabrication, a semiconductor package 10 may be eventually manufactured.

According to some embodiments, as discussed in FIG. 8L, the preliminary package IP may be delivered to be mounted on the package substrate 600. In the delivery of the preliminary package IP, the molding layer 300 may prevent or reduce damage to the second semiconductor chip 220 and the chip stacks 200. For example, the preliminary package 1P may be configured such that the molding layer 300 may cover the second sidewall 20S2 of the first lower semiconductor chip 210A to protect the first lower semiconductor chip 210A.

The partial removal of the molding layer 300 may be performed after the delivery of the preliminary package IP is terminated. For example, as discussed in FIG. 8M, after the preliminary package IP is mounted on the package substrate 600, the molding layer 300 may be removed. After that, the stiffener 700 may be formed on the package substrate 600. Accordingly, even when the second sidewall 20S2 of the first lower semiconductor chip 210A is exposed, the stiffener 700 may protect the first lower semiconductor chip 210A.

According to the present inventive concepts, a molding layer may not be provided on a sidewall of a first semiconductor chip, and the sidewall of the first semiconductor chip may be exposed externally. Therefore, the occurrence of a crack may be prevented or reduced between the molding layer and the first semiconductor chip. Accordingly, it may be possible to prevent or reduce propagation of a crack into bumps. A semiconductor package may have increased reliability.

The molding layer may be provided between the first semiconductor chip and a second semiconductor chip on a central region. The molding layer may prevent or reduce warpage of a semiconductor package.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%)).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

This detailed description of the present inventive concepts should not be construed as limited to the embodiments set forth herein, and it is intended that the present inventive concepts cover the various combinations, the modifications and variations of this invention without departing from the spirit and scope of the present inventive concepts.

What is claimed is:

1. A semiconductor package, comprising:
a substrate;
a first semiconductor chip on the substrate, the first semiconductor chip having a first sidewall and a second sidewall different from the first sidewall;
a second semiconductor chip on the substrate and laterally spaced apart from the first semiconductor chip; and
a molding layer on the substrate, the molding layer being between the first sidewall of the first semiconductor chip and a sidewall of the second semiconductor chip,
wherein the molding layer exposes the second sidewall of the first semiconductor chip.

2. The semiconductor package of claim 1, further comprising:
a plurality of bumps between the substrate and the first semiconductor chip; and
an under-fill layer between the substrate and the first semiconductor chip, the under-fill layer covering sidewalls of the plurality of bumps,
wherein the second sidewall of the first semiconductor chip is vertically aligned with an outer sidewall of the under-fill layer.

3. The semiconductor package of claim 1, wherein the second sidewall of the first semiconductor chip is exposed to an external space and in contact with air.

4. The semiconductor package of claim 1, wherein the molding layer includes:
a first part between the first semiconductor chip and the second semiconductor chip; and
a second part on a top surface at an edge region of the substrate,
wherein, when viewed in plan, the edge region of the substrate is between the second sidewall of the first semiconductor chip and a sidewall of the substrate, and
wherein a top surface of the second part of the molding layer is at a level lower than a level of a top surface of the first part of the molding layer.

5. The semiconductor package of claim 1, further comprising an upper semiconductor chip on the first semiconductor chip, the upper semiconductor chip having a first lateral surface and a second lateral surface different from the first lateral surface,
wherein the molding layer is on the first lateral surface of the upper semiconductor chip, and
wherein the molding layer is not on the second lateral surface of the upper semiconductor chip.

6. The semiconductor package of claim 5, further comprising a molding pattern on a top surface of the first semiconductor chip, the molding pattern covering the first lateral surface of the upper semiconductor chip,
wherein the molding pattern is between the molding layer and the first lateral surface of the upper semiconductor chip.

7. The semiconductor package of claim 6, wherein
the molding pattern further covers the second lateral surface of the upper semiconductor chip, and
an outer sidewall of the molding pattern is vertically aligned with the second sidewall of the first semiconductor chip.

8. The semiconductor package of claim 6, wherein the molding pattern exposes the second lateral surface of the upper semiconductor chip.

9. The semiconductor package of claim 1, wherein
the first semiconductor chip includes a first semiconductor die and a plurality of conductive pads,
the second semiconductor chip includes a second semiconductor die and a plurality of chip pads, and
a coefficient of thermal expansion of the molding layer is greater than a coefficient of thermal expansion of the first semiconductor die and greater than a coefficient of thermal expansion of the second semiconductor die.

10. The semiconductor package of claim 1, wherein a height of the molding layer is between about 5 times to about 10 times a height of the substrate.

11. A semiconductor package, comprising:
a substrate that has a central region and an edge region when viewed in plan;
a first semiconductor chip on the central region of the substrate, the first semiconductor chip having a first sidewall and a second sidewall that are different from each other;
a plurality of bumps between the substrate and the first semiconductor chip;
a second semiconductor chip provided on the central region of the substrate and laterally spaced apart from the first semiconductor chip; and
a molding layer on the central region and the edge region of the substrate, the molding layer covering the first sidewall of the first semiconductor chip and a sidewall of the second semiconductor chip,
wherein, when viewed in plan, the edge region of the substrate is between the second sidewall of the first semiconductor chip and a sidewall of the substrate, and
wherein a height of the molding layer on the edge region of the substrate is less than a height of the bumps.

12. The semiconductor package of claim 11, wherein
the molding layer is further on the second sidewall of the first semiconductor chip, and
a thickness of the molding layer on the second sidewall of the first semiconductor chip is equal to or less than about 200 μm.

13. The semiconductor package of claim 11, wherein
the second sidewall of the first semiconductor chip is exposed to an external space, and
the molding layer does not cover the second sidewall of the first semiconductor chip.

14. The semiconductor package of claim 13, further comprising an under-fill layer between the substrate and the first semiconductor chip, the under-fill layer encapsulating the bumps,
wherein a height of the under-fill layer on the edge region of the substrate is less than a height of the under-fill layer on a bottom surface of the first semiconductor chip.

15. The semiconductor package of claim 11, wherein
the height of the molding layer on the edge region of the substrate is less than a height of the molding layer on the central region of the substrate, and
the molding layer on the central region of the substrate is coplanar with a top surface of the second semiconductor chip.

16. A semiconductor package, comprising:
a package substrate;
a plurality of solder terminals on a bottom surface of the package substrate;
an interposer substrate on a top surface of the package substrate;
a plurality of connection solders between the package substrate and the interposer substrate;
a first semiconductor chip on a top surface of the interposer substrate, the first semiconductor chip having a first sidewall and a second sidewall different from the first sidewall;
a second semiconductor chip provided on the top surface of the interposer substrate and laterally spaced apart from the first semiconductor chip;
a plurality of first bumps between the interposer substrate and the first semiconductor chip;
a plurality of second bumps between the interposer substrate and the second semiconductor chip;
an under-fill layer between the interposer substrate and the first semiconductor chip, the under-fill layer encapsulating the first bumps; and
a molding layer on the interposer substrate, the molding layer covering the first sidewall of the first semiconductor chip and a sidewall of the second semiconductor chip,
wherein the interposer substrate includes a semiconductor die, a plurality of through vias, a plurality of wiring structures, and a plurality of interposer pads,
wherein the first semiconductor chip includes a first semiconductor die and a plurality of conductive pads,
wherein the second semiconductor chip includes a second semiconductor die and a plurality of chip pads,
wherein a coefficient of thermal expansion of the molding layer is greater than a coefficient of thermal expansion of the semiconductor die, greater than a coefficient of thermal expansion of the first semiconductor die, and greater than a coefficient of thermal expansion of the second semiconductor die, and
wherein the molding layer externally exposes the second sidewall of the first semiconductor chip.

17. The semiconductor package of claim 16, further comprising:
a plurality of upper semiconductor chips stacked on a top surface of the first semiconductor chip;
a plurality of conductive bumps provided between and coupled to the upper semiconductor chips;
an under-fill pattern between the upper semiconductor chips, the under-fill pattern encapsulating the conductive bumps; and
a molding pattern on the top surface of the first semiconductor chip, the molding pattern covering sidewalls of the upper semiconductor chips,
wherein the first semiconductor chip includes a plurality of conductive vias,
wherein the molding pattern is between the molding layer and the upper semiconductor chips, and
wherein the second sidewall of the first semiconductor chip is vertically aligned with an outer sidewall of the under-fill layer.

18. The semiconductor package of claim 17, wherein the second sidewall of the first semiconductor chip is vertically aligned with an outer sidewall of the molding pattern.

19. The semiconductor package of claim 17, wherein
the sidewalls of the upper semiconductor chips have first lateral surfaces and second lateral surfaces that are opposite to the first lateral surfaces,
the molding pattern covers the first lateral surfaces of the upper semiconductor chips and exposes the second lateral surfaces of the upper semiconductor chips, and
the second lateral surfaces of the upper semiconductor chips are vertically aligned with an outer sidewall of the under-fill pattern.

20. The semiconductor package of claim 16, further comprising:
a lower under-fill layer between the package substrate and the interposer substrate, the lower under-fill layer covering sidewalls of the connection solders; and
a stiffener on a top surface at an edge region of the package substrate, the stiffener being laterally spaced apart from the molding layer and the first semiconductor chip,
wherein the second sidewall of the first semiconductor chip faces the stiffener.
